(19) United States
(12) Patent Application Publication
(10) Pub. No.: US 2013/0256802 A1
(43) Pub. Date: Oct. 3, 2013

(54) Replacement Gate With Reduced Gate Leakage Current

(71) Applicants: Hemanth Jagannathan, Guilderland, NY (US); Ramachandra Divakaruni, Ossining, NY (US); Unoh Kwon, Fishkill, NY (US); Vijay Narayanan, New York, NY (US); Ravikumar Ramachandran, Pleasantville, NY (US)

(72) Inventors: Hemanth Jagannathan, Guilderland, NY (US); Ramachandra Divakaruni, Ossining, NY (US); Unoh Kwon, Fishkill, NY (US); Vijay Narayanan, New York, NY (US); Ravikumar Ramachandran, Pleasantville, NY (US)

(73) Assignee: International Business Machines Corporation, Armonk, NY (US)

(21) Appl. No.: 13/430,755

(22) Filed: Mar. 27, 2012

(51) Int. Cl. H01L 27/088; H01L 21/283

(52) U.S. Cl. 257/368; 438/591; 257/E27.06; 257/E21.159

(57) ABSTRACT

Replacement gate work function material stacks are provided, which provides a work function about the energy level of the conduction band of silicon. After removal of a disposable gate stack, a gate dielectric layer is formed in a gate cavity. A metallic compound layer including a metal and a non-metal element is deposited directly on the gate dielectric layer. At least one barrier layer and a conductive material layer is deposited and planarized to fill the gate cavity. The metallic compound layer includes a material, which provides, in combination with other layer, a work function about 4.4 eV or less, and can include a material selected from tantalum carbide, metallic nitrides, and a hafnium-silicon alloy. Thus, the metallic compound layer can provide a work function that enhances the performance of an n-type field effect transistor employing a silicon channel. Optionally, carbon doping can be introduced in the channel.

### BACKGROUND

The present disclosure generally relates to semiconductor devices, and particularly to semiconductor structures having dual work function material gates and a high-k gate dielectric, and methods of manufacturing the same.

High gate leakage current of silicon oxide and nitrided silicon dioxide as well as depletion effect of polysilicon gate electrodes limits the performance of conventional semiconductor oxide based gate electrodes. High performance devices for an equivalent oxide thickness (EOT) less than 2 nm require high dielectric constant (high-k) gate dielectrics and metal gate electrodes to limit the gate leakage current and provide high on-currents. Materials for high-k gate dielectrics include ZrO₂, HfO₂, other dielectric metal oxides, alloys thereof, and their silicate alloys.

In general, dual metal gate complementary metal oxide semiconductor (CMOS) integration schemes employ two gate materials, one having a work function near the valence band edge of the semiconductor material in the channel and the other having a work function near the conduction band edge of the same semiconductor material. In CMOS devices having a silicon channel, a conductive material having a work function near 4.0 eV is necessary for n-type metal oxide semiconductor field effect transistors (NMOSFETs, or “NFETs”) and another conductive material having a work function near 5.1 eV is necessary for p-type metal oxide semiconductor field effect transistors (PMOSFETs, or “PFETs”). In conventional CMOS devices employing polysilicon gate materials, a heavily p-doped polysilicon gate and a heavily n-doped polysilicon gate are employed to address the needs. In CMOS devices employing high-k gate dielectric materials, two types of gate stacks comprising suitable materials satisfying the work function requirements are needed for the PFETs and for the NFETS, in which the gate stack for the PFETs provides a flat band voltage closer to the valence band edge of the material of the channel of the PFETs, and the gate stack for the NFETs provides a flat band voltage closer to the conduction band edge of the material of the channel of the NFETs. In other words, threshold voltages need to be optimized differently between the PFETs and the NFETs.

A challenge in semiconductor technology has been to provide two types of gate electrodes having a first work function at or near the valence band edge and a second work function at or near the conduction band edge of the underlying semiconductor material such as silicon. This challenge has been particularly difficult because the two types of gate electrodes are also required to be a metallic material having a high electrical conductivity.

### BRIEF SUMMARY

Replacement gate work function material stacks are provided, which provide a work function about the energy level of the conduction band of silicon. After removal of a disposable gate stack, a gate dielectric layer is formed in a gate cavity. A metallic compound layer including a metal and a non-metal element is deposited directly on the gate dielectric layer. At least one barrier layer and a conductive material layer are deposited and planarized to fill the gate cavity. The metallic compound layer includes a material, which provides, in combination with other layers, a work function about 4.0 eV, and specifically, less than 4.4 eV, and can include a material selected from tantalum carbide, metallic nitrides, and a hafnium-silicon alloy. Thus, the metallic compound layer can provide a work function that enhances the performance of an n-type field effect transistor employing a silicon channel.

According to an aspect of the present disclosure, a semiconductor structure is provided, which includes a first field effect transistor and a second field effect transistor. The first field effect transistor has a first gate dielectric. The first gate dielectric includes a first interfacial dielectric layer contacting a channel of the first field effect transistor, a planar metal-doped gate dielectric layer contacting a top surface of the first interfacial dielectric layer, and a first U-shaped gate dielectric layer having a horizontal portion in contact with the planar metal-doped gate dielectric layer and a vertical portion that extends to a topmost portion of a first dielectric gate spacer laterally surrounding the first U-shaped gate dielectric layer. The second field effect transistor has a second gate dielectric. The second gate dielectric includes a second interfacial dielectric layer contacting a channel of the second field effect transistor, and a second U-shaped gate dielectric layer having a horizontal portion in contact with the second interfacial dielectric layer and a vertical portion that extends to a topmost portion of a second dielectric gate spacer laterally surrounding the second U-shaped gate dielectric layer.

According to another aspect of the present disclosure, a method of forming a semiconductor structure is provided, which includes: forming an interfacial dielectric layer at a bottom surface of a cavity laterally enclosed by a dielectric gate spacer and over a semiconductor substrate; forming a gate dielectric layer having a dielectric constant greater than 3.9 on the interfacial dielectric layer and on inner sidewalls of the dielectric gate spacer; forming a metal-containing layer on the gate dielectric layer; annealing the metal-containing layer, wherein a metallic element within the metal-containing layer diffuses through the gate dielectric layer and at least to an interface between the interfacial dielectric layer and the gate dielectric layer; and removing the metal-containing layer selective to the gate dielectric layer.

### BRIEF DESCRIPTION OF THE SEVERAL VIEWS OF THE DRAWINGS

FIG. 1 is vertical cross-sectional view of a first exemplary semiconductor structure after formation of disposable gate structures and formation of a planar dielectric surface on a planarization dielectric layer according to a first embodiment of the present disclosure.

FIG. 2 is a vertical cross-sectional view of the first exemplary semiconductor structure after removal of the disposable gate structures according to the first embodiment of the present disclosure.

FIG. 3 is a vertical cross-sectional view of the first exemplary semiconductor structure after formation of a gate dielectric layer according to the first embodiment of the present disclosure.

FIG. 4 is a vertical cross-sectional view of the first exemplary semiconductor structure after formation of a diffusion barrier layer according to the first embodiment of the present disclosure.

FIG. 5 is a vertical cross-sectional view of the first exemplary semiconductor structure after patterning of the diffusion barrier layer according to the first embodiment of the present disclosure.

FIG. 6 is a vertical cross-sectional view of the first exemplary semiconductor structure after formation of a metal-containing layer and a sacrificial metal-containing cap layer according to the first embodiment of the present disclosure.

FIG. 7 is a vertical cross-sectional view of the first exemplary semiconductor structure after formation of a semiconductor material layer according to the first embodiment of the present disclosure.

FIG. 8 is a vertical cross-sectional view of the first exemplary semiconductor structure after a drive-in anneal and formation of a planar metal doped gate dielectric layer according to the first embodiment of the present disclosure.

FIG. 9 is a vertical cross-sectional view of the first exemplary semiconductor structure with the metal doped gate dielectric layer after removal of the semiconductor material layer, the sacrificial metal-containing cap layer, the metal-containing layer, and the diffusion barrier layer according to the first embodiment of the present disclosure.

FIG. 10 is a vertical cross-sectional view of the first exemplary semiconductor structure after formation of a first work function material layer according to the first embodiment of the present disclosure.

FIG. 11 is a vertical cross-sectional view of the first exemplary semiconductor structure after application of a photoresist and lithographic patterning of the first work function material layer according to the first embodiment of the present disclosure.

FIG. 12 is a vertical cross-sectional view of the first exemplary semiconductor structure after removal of the photoresist and formation of a second work function material layer according to the first embodiment of the present disclosure.

FIG. 13 is a vertical cross-sectional view of the first exemplary semiconductor structure after deposition of an optional metallic barrier layer and a conductive material layer according to the first embodiment of the present disclosure.

FIG. 14 is a vertical cross-sectional view of the first exemplary semiconductor structure after planarization according to the first embodiment of the present disclosure.

FIG. 15 is a vertical cross-sectional view of the first exemplary semiconductor structure after formation of a contact-level dielectric layer and contact via structures according to the first embodiment of the present disclosure.

FIG. 16 is a vertical cross-sectional view of a first variation of the first exemplary semiconductor structure according to the first embodiment of the present disclosure.

FIG. 17 is a vertical cross-sectional view of a second variation of the first exemplary semiconductor structure after formation of a work function material layer, an optional metallic barrier layer, and a conductive material layer according to the first embodiment of the present disclosure.

FIG. 18 is a vertical cross-sectional view of the second variation of the first exemplary semiconductor structure after formation of a contact-level dielectric layer and contact via structures according to the first embodiment of the present disclosure.

FIG. 19 is a vertical cross-sectional view of a second exemplary semiconductor structure after application and lithographic patterning of an optional dielectric liner and a photoresist layer according to a second embodiment of the present disclosure.

FIG. 20 is a vertical cross-sectional view of the second exemplary semiconductor structure after implantation of carbon to form a carbon doped region according the second embodiment of the present disclosure.

FIG. 21 is a vertical cross-sectional view of the second exemplary semiconductor structure after removal of the photoresist layer and the optional dielectric liner according to the second embodiment of the present disclosure.

FIG. 22 is a vertical cross-sectional view of the second exemplary semiconductor structure after formation of a contact-level dielectric layer and contact via structures according to the second embodiment of the present disclosure.

FIG. 23 is a vertical cross-sectional view of a third exemplary semiconductor structure after application and lithographic patterning of an optional dielectric liner and a photoresist layer according to a third embodiment of the present disclosure.

FIG. 24 is a vertical cross-sectional view of the third exemplary semiconductor structure after implantation of carbon to form a carbon doped region according the third embodiment of the present disclosure.

FIG. 25 is a vertical cross-sectional view of the third exemplary semiconductor structure after removal of the photoresist layer and the optional dielectric liner according to the third embodiment of the present disclosure.

FIG. 26 is a vertical cross-sectional view of the third exemplary semiconductor structure after formation of a contact-level dielectric layer and contact via structures according to the third embodiment of the present disclosure.

### DETAILED DESCRIPTION

As stated above, the present disclosure relates to semiconductor structures having dual work function material gates and a high-k gate dielectric, and methods of manufacturing the same, which are now described in detail with accompanying figures. Like and corresponding elements mentioned herein and illustrated in the drawings are referred to by like reference numerals. The drawings are not necessarily drawn to scale.

As used herein, ordinals such as “first,” “second,” and “third” are employed merely to distinguish similar elements, and different ordinals may be employed to designate a same element in the specification and/or claims.

As used herein, a field effect transistor refers to any planar transistor having a gate electrode overlying a horizontal planar channel, any fin field effect transistor having a gate electrode located on sidewalls of a semiconductor fin, or any other types of metal-oxide semiconductor field effect transistor (MOSFETs) and junction field effect transistors (JFETs).

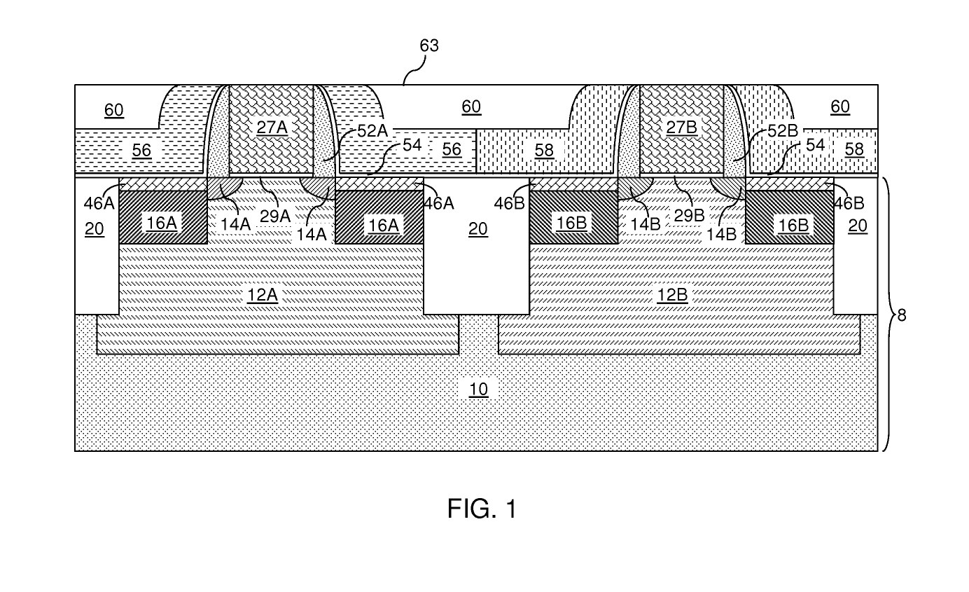

Referring to FIG. 1, a first exemplary semiconductor structure according to a first embodiment of the present disclosure includes a semiconductor substrate 8, on which various components of field effect transistors are formed. The semiconductor substrate 8 can be a bulk substrate including a bulk semiconductor material throughout, or a semiconductor-on-insulator (SOI) substrate (not shown) containing a top semiconductor layer, a buried insulator layer located under the top semiconductor layer, and a bottom semiconductor layer located under the buried insulator layer.

Various portions of the semiconductor material in the semiconductor substrate 8 can be doped with electrical dopants of n-type or p-type at different dopant concentration levels. For example, the semiconductor substrate 8 may include an underlying semiconductor layer 10, a first doped well 12A formed in a first device region (the region to the left in FIG. 1), and an second doped well 12B formed in a second device region (the region to the right in FIG. 1). Each of the first doped well 12A and the second doped well 12B can be independently doped with n-type electrical dopants or p-type electrical dopants. Thus, each of the first doped well 12A and the second doped well 12B can be an n-type well or a p-type well.

Shallow trench isolation structures 20 are formed to laterally separate each of the second doped well 12B and the first doped well 12A. Typically, each of the second doped well 12B and the first doped well 12A is laterally surrounded by a contiguous portion of the shallow trench isolation structures 20. If the semiconductor substrate 8 is a semiconductor-on-insulator substrate, bottom surfaces of the second doped well 12B and the first doped well 12A may contact a buried insulator layer (not shown), which electrically isolates each of the second doped well 12B and the first doped well 12A from other semiconductor portions of the semiconductor substrate 8 in conjunction with the shallow trench isolation structures 20.

A disposable dielectric layer and a disposable gate material layer are deposited and lithographically patterned to form disposable gate structures. For example, the disposable gate stacks may include a first disposable gate structure that is a stack of a first disposable dielectric portion 29A and a first disposable gate material portion 27A and a second disposable gate structure that is a stack of a second disposable dielectric portion 29B and a second disposable gate material portion 27B. The disposable dielectric layer includes a dielectric material such as a semiconductor oxide. The disposable gate material layer includes a material that can be subsequently removed selective to dielectric material such as a semiconductor material. The first disposable gate structure (29A, 27A) is formed over the first doped well 12A, and the second disposable gate structure (29B, 27B) is formed over the second doped well 12B. The height of the first disposable gate structure (29A, 27A) and the second disposable gate structure (29B, 27B) can be from 20 nm to 500 nm, and typically from 40 nm to 250 nm, although lesser and greater heights can also be employed.

First electrical dopants are implanted into portions of the first doped well 12A that are not covered by the first disposable gate structure (29A, 27A) to form first source and drain extension regions 14A. The second doped well 12B can be masked by a photoresist (not shown) during the implantation of the first electrical dopants to prevent implantation of the first electrical dopants therein. In one embodiment, the first electrical dopants have the opposite polarity of the polarity of doping of the first doped well 12A. For example, the first doped well 12A can be a p-type well and the first electrical dopants can be n-type dopants such as P, As, or Sb. Alternatively, the first doped well 12A can be an n-type well and the first electrical dopants can be p-type dopants such as B, Ga, and In.

Second electrical dopants are implanted into portions of the second doped well 12B that are not covered by the second disposable gate structure (29B, 27B) to form second source and drain extension regions 14B. The first doped well 12A can be masked by a photoresist (not shown) during the implantation of the second electrical dopants to prevent implantation of the second electrical dopants therein. For example, the second doped well 12B can be an n-type well and the second electrical dopants can be p-type dopants. Alternatively, the second doped well 12B can be a p-type well and the second electrical dopants can be n-type dopants.

Dielectric gate spacers are formed on sidewalls of each of the disposable gate structures, for example, by deposition of a conformal dielectric material layer and an anisotropic etch. The dielectric gate spacers include a first dielectric gate spacer 52A formed around the first disposable gate structure (29A, 27A) and a second dielectric gate spacer 52B formed around the second disposable gate structure (29B, 27B).

Dopants having the same conductivity type as the first electrical dopants are implanted into portions of the first doped well 12A that are not covered by the first disposable gate structure (29A, 27A) and the first dielectric gate spacer 52A to form first source and drain regions 16A. The second doped well 12B can be masked by a photoresist (not shown) during this implantation to prevent undesired implantation therein. Similarly, dopants having the same conductivity type as the second electrical dopants are implanted into portions of the second doped well 12B that are not covered by the second disposable gate structure (29B, 27B) and the second dielectric gate spacer 52B to form second source and drain regions 16B. The first doped well 12A can be masked by a photoresist (not shown) during this implantation to prevent undesired implantation therein.

In some embodiments, the first source and drain regions 16A and/or the second source and drain regions 16B can be formed by replacement of the semiconductor material in the first doped well 12A and/or the semiconductor material in the second doped well 12B with a new semiconductor material having a different lattice constant. In this case, the new semiconductor material(s) is/are typically epitaxially aligned with (a) single crystalline semiconductor material(s) of the first doped well 12A and/or the semiconductor material in the second doped well 12B, and apply/applies a compressive stress or a tensile stress to the semiconductor material of the first doped well 12A and/or the semiconductor material in the second doped well 12B between the first source and drain extension regions 14A and/or between the second source and drain extension regions 14B.

First metal semiconductor alloy portions 46A and second metal semiconductor alloy portions 46B are formed on exposed semiconductor material on the top surface of the semiconductor substrate 8, for example, by deposition of a metal layer (not shown) and an anneal. Unreacted portions of the metal layer are removed selective to reacted portions of the metal layer. The reacted portions of the metal layer constitute the metal semiconductor alloy portions (46A, 46B), which can include a metal silicide portions if the semiconductor material of the first and second source and drain regions (16A, 16B) include silicon.

Optionally, a dielectric liner 54 may be deposited over the metal semiconductor alloy portions 54, the first and second disposable gate structures (29A, 27A, 29B, 27B), and the first and second dielectric gate spacers (52A, 52B). A first stress-generating liner 58 and a second stress-generating liner 56 can be formed over the first disposable gate structure (29A, 27A) and the second disposable gate structure (29B, 27B), respectively. Each of the first stress-generating liner 58 and the second stress-generating liner 56 can include a dielectric material that generates a compressive stress or a tensile stress to underlying structures, and can be silicon nitride layers deposited by plasma enhanced chemical vapor deposition under various plasma conditions.

A planarization dielectric layer 60 is deposited over the first stress-generating liner 58 and/or the second stress-generating liner 56, if present, or over the metal semiconductor alloy portions 54, the first and second disposable gate structures (29A, 27A, 29B, 27B), and the first and second dielectric gate spacers (52A, 52B) if (a) stress-generating liner(s) is/are not present. Preferably, the planarization dielectric layer 60 is a dielectric material that may be easily planarized. For example, the planarization dielectric layer 60 can be a doped silicate glass or an undoped silicate glass (silicon oxide).

The planarization dielectric layer 60, the first stress-generating liner 58 and/or the second stress-generating liner 56 (if present), and the dielectric liner 54 (if present) are planarized above the topmost surfaces of the first and second disposable gate structures (29A, 27A, 29B, 27B), i.e., above the topmost surfaces of the first and second disposable gate material portions (27A, 27B). The planarization can be performed, for example, by chemical mechanical planarization (CMP). The planar topmost surface of the planarization dielectric layer 60 is herein referred to as a planar dielectric surface 63.

The combination of the first source and drain extension regions 14A, the first source and drain regions 16A, and the first doped well 12A can be employed to subsequently form a first field effect transistor. The combination of the second source and drain extension regions 14B, the second source and drain regions 16B, and the second doped well 12B can be employed to subsequently form a second field effect transistor. The first stress-generating liner 58 can apply a tensile stress to the first channel of the first field effect transistor, and the second stress-generating liner 56 can apply a compressive stress to the second channel of the second field effect transistor.

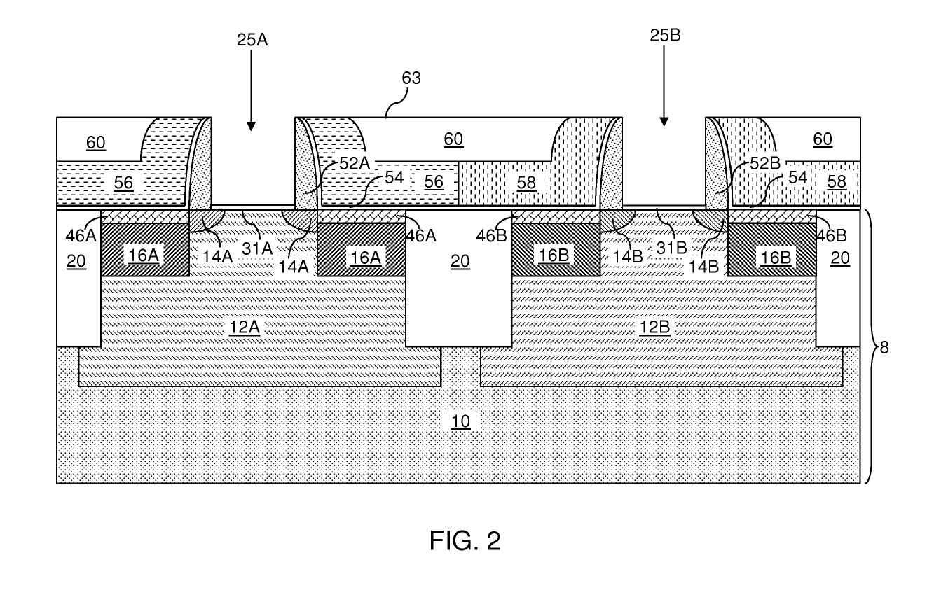

Referring to FIG. 2, the first disposable gate structure (29A, 27A) and the second disposable gate structure (29B, 27B) are removed by at least one etch. The at least one etch can be a recess etch, which can be an isotropic etch or anisotropic etch. The etch employed to remove the first and second disposable gate material portions (27A, 27B) is selective to the dielectric materials of the planarization dielectric layer 60, the first stress-generating liner 58 and/or the second stress-generating liner 56 (if present), and the first and second dielectric gate spacers (52A, 52B). Optionally, one or both of the dielectric portions (29A, 29B) can be left by etching selective to these layers. The disposable gate structures (29A, 27A, 29B, 27B) are recessed below the planar dielectric surface 63 to expose the semiconductor surfaces above the first channel and the second channel to form gate cavities (25A, 25B) over the semiconductor substrate. The first gate cavity 25A is laterally enclosed by the first dielectric gate spacer 52A, and the second gate cavity 25B is laterally enclosed by the second dielectric gate spacer 52B.

Optionally, a first interfacial dielectric layer 31A can be formed on the exposed surface of the first doped well 12A by conversion of the exposed semiconductor material into a dielectric material, and a second interfacial dielectric layer 31B can be formed on the exposed surface of the second doped well 12B by conversion of the exposed semiconductor material into the dielectric material. Each of the first and second interfacial dielectric layers (31A, 31B) can be a semiconductor-element-containing dielectric layer. The formation of the interfacial dielectric layers (31A, 31B) can be effected by thermal conversion or plasma treatment. If the semiconductor material of the first doped well 12A and the second doped well 12B includes silicon, the interfacial dielectric layers (31A, 31B) can include silicon oxide or silicon nitride. The interfacial dielectric layers (31A, 31B) contact a semiconductor surface underneath and gate dielectrics to be subsequently deposited thereupon. In one embodiment, the first interfacial dielectric layer 31A and the second interfacial dielectric layer 31B can have a same composition and a same thickness.

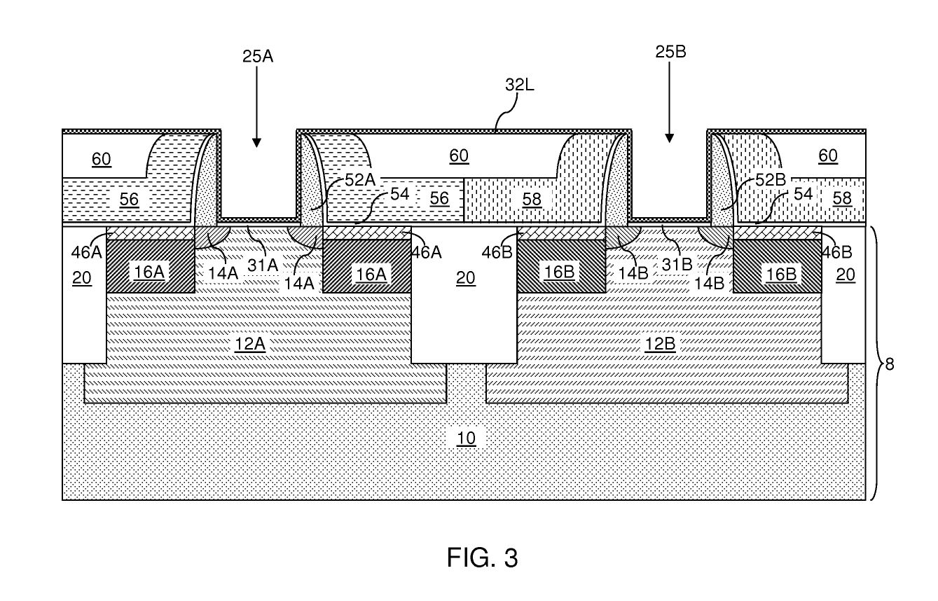

Referring to FIG. 3, a gate dielectric layer 32L is deposited on the first and second interfacial dielectric layers (31A, 31B) and on inner sidewalls of the first and second dielectric gate spacers (52A, 52B). The gate dielectric layer 32L can be deposited as a contiguous gate dielectric layer that contiguously covers all top surfaces of the planarization dielectric layer 60, the first stress-generating liner 58 and/or the second stress-generating liner 56 (if present), all sidewall surfaces of the first and second dielectric gate spacers (52A, 52B), and all top surfaces of the first and second interfacial dielectric layers (31A, 31B).

The gate dielectric layer 32L can be a high dielectric constant (high-k) material layer having a dielectric constant greater than 3.9. The gate dielectric layer 32L can include a dielectric metal oxide, which is a high-k material containing a metal and oxygen, and is known in the art as high-k gate dielectric materials. Dielectric metal oxides can be deposited by methods well known in the art including, for example, chemical vapor deposition (CVD), physical vapor deposition (PVD), molecular beam deposition (MBD), pulsed laser deposition (PLD), liquid source misted chemical deposition (LSMCD), atomic layer deposition (ALD), etc.

Exemplary high-k dielectric material include HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, a silicate thereof, and an alloy thereof. Each value of x is independently from 0.5 to 3 and each value of y is independently from 0 to 2. The thickness of the gate dielectric layer 32L, as measured at horizontal portions, can be from 0.9 nm to 6 nm, and from 1.0 nm to 3 nm. The gate dielectric layer 32L may have an effective oxide thickness on the order of or less than 2 nm. In one embodiment, the gate dielectric layer 32L is a hafnium oxide (HfO₂) layer.

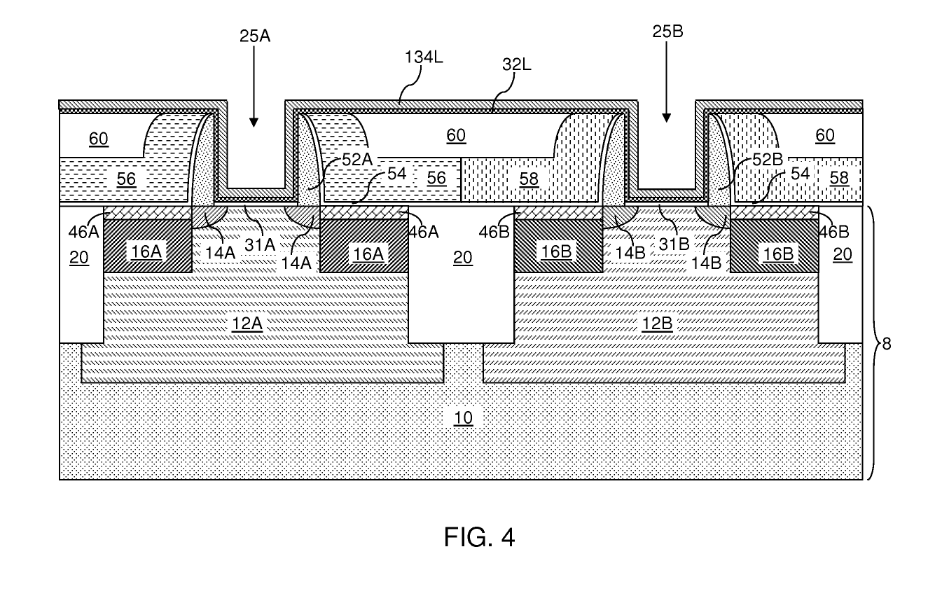

Referring to FIG. 4, a diffusion barrier layer 134L is formed on the surfaces of the gate dielectric layer 32L. The diffusion barrier layer 134L includes a material that prevents diffusion of metallic elements. In one embodiment, the diffusion barrier layer 134L can include a metallic nitride layer. In one embodiment, the diffusion barrier layer 134L can include one or more of TiN, TaN, and WN. In another embodiment, the diffusion barrier layer 134L can include a metallic carbide layer. The diffusion barrier layer 134L can be deposited by physical vapor deposition (PVD), atomic layer deposition (ALD), and/or chemical vapor deposition (CVD). The thickness of the diffusion barrier layer 134L, as measured at a horizontal portion above the first or second interfacial dielectric layer (31A, 31B) can be from 1 nm to 10 nm, although lesser and greater thicknesses can also be employed.

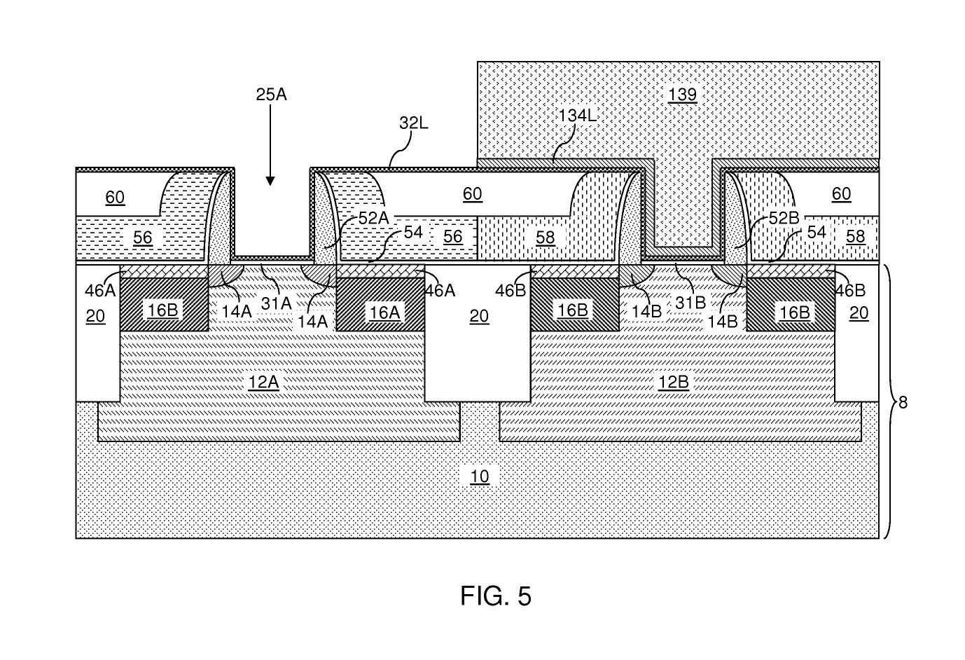

Referring to FIG. 5, the diffusion barrier layer 134L is patterned, for example, by applying a photoresist layer 139, lithographically patterning the photoresist layer 139 by exposure and development, and etching physically exposed portions of the diffusion barrier layer 134L employing remaining portions of the diffusion barrier layer 134L as an etch mask. The diffusion barrier layer 134L is removed in the first device region, and remains in the second device region. Thus, the diffusion barrier layer 134L is removed from above the first interfacial dielectric layer 31A, while the diffusion barrier layer 134L remains over the second interfacial dielectric layer 31B. The photoresist layer 139 is subsequently removed, for example, by ashing.

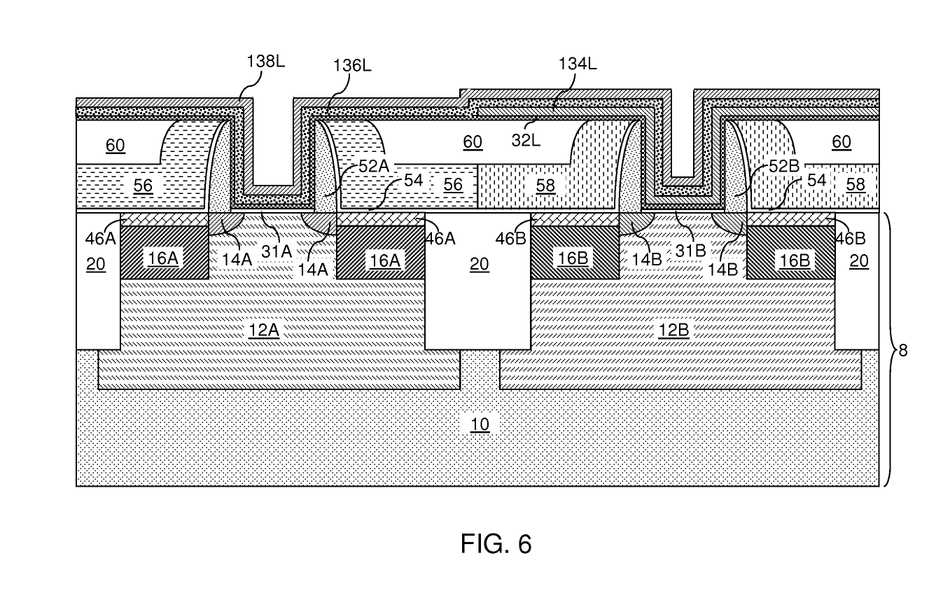

Referring to FIG. 6, a metal-containing layer 136L and a sacrificial metal-containing cap layer 138L are sequentially deposited over the diffusion barrier layer 134L and the gate dielectric layer 32L. The metal-containing layer 136L includes at least one metallic element that can dope the dielectric material of the gate dielectric layer 32L to alter the dielectric characteristics of the dielectric material. For example, the at least one metallic element can be selected from Group IIA elements, Group IIIB elements, Al, Ge, and Ti. Group IIA elements include Be, Mg, Ca, Sr, Ba, and Ra. Group IIIB elements include Sc, Y, all Lanthanide elements, and all Actinide elements.

In one embodiment, the metal-containing layer 136L is a metal layer consisting of at least one metallic element selected from Group IIA elements, Group IIIB elements, Al, Ge, and Ti. In another embodiment, the metal-containing layer 136L is a conductive metallic material layer including a nitride or a carbide of at least one metallic element selected from Group IIA elements, Group IIIB elements, Al, Ge, and Ti. In yet another embodiment, the metal-containing layer 136L is a dielectric compound, e.g., an oxide or a nitride, of at least one metallic element selected from Group IIA elements, Group IIIB elements, Al, Ge, and Ti.

The metal-containing layer 136L can be deposited conformally or non-conformally. The metal-containing layer 136L can be deposited, for example, by physical vapor deposition (PVD), chemical vapor deposition (CVD), atomic layer deposition (ALD), or a combination thereof. The thickness of the metal-containing layer 136L, as measured over the first or second interfacial dielectric layer (31A, 31B), can be from 0.2 nm to 5 nm, although lesser and greater thicknesses can also be employed.

The sacrificial metal-containing cap layer 138L includes a metallic material that prevents outdiffusion of the material of the metal-containing layer 136L during a subsequent anneal step. The sacrificial metal-containing cap layer 138L can include a metal nitride, a metal carbide, and/or a metal oxide, and/or a metal nitride. For example, the sacrificial metal-containing cap layer 138 can include TiN, TaN, WN, TiC, TaC, and/or WC.

The sacrificial metal-containing cap layer 138L can be deposited conformally or non-conformally. The sacrificial metal-containing cap layer 138L can be deposited, for example, by physical vapor deposition (PVD), chemical vapor deposition (CVD), atomic layer deposition (ALD), or a combination thereof. The thickness of the sacrificial metal-containing cap layer 138L, as measured over the first or second interfacial dielectric layer (31A, 31B), can be from 1 nm to 20 nm, although lesser and greater thicknesses can also be employed. In one embodiment, the sacrificial metal-containing cap layer 138L includes a material that does not form any metal-semiconductor alloy such as a metal silicide.

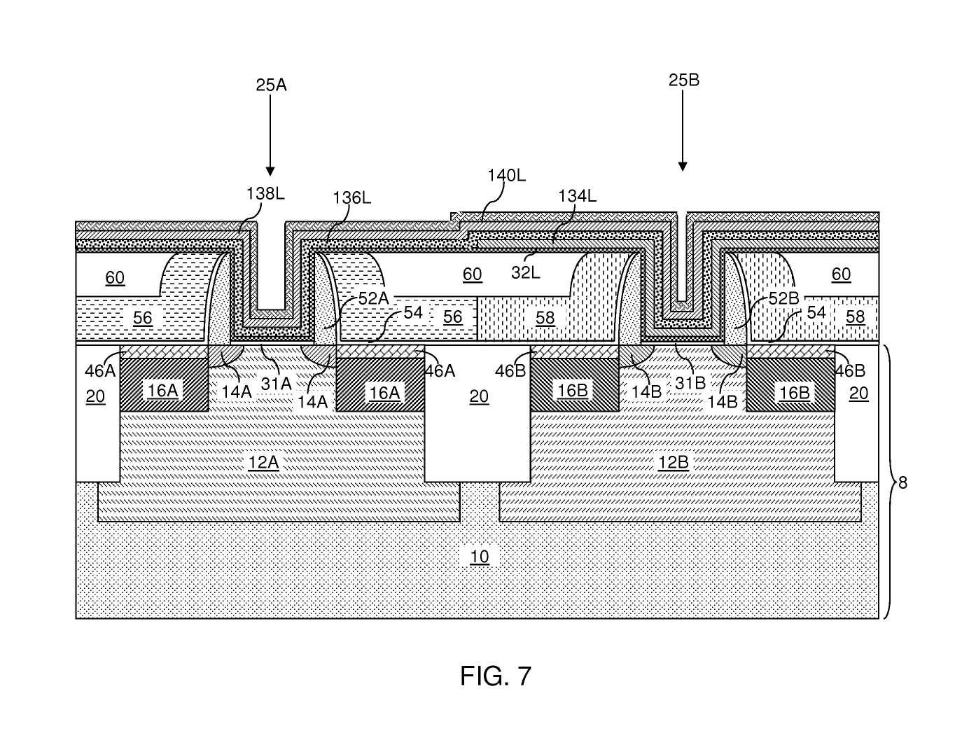

Referring to FIG. 7, a semiconductor material layer 140L can be optionally deposited over the sacrificial metal-containing cap layer 138. The semiconductor material layer 140L can include a semiconductor material. The semiconductor material can include at least one elemental semiconductor material such as silicon and germanium, and/or at least one compound semiconductor material as known in the art. For example, the semiconductor material can include polysilicon or amorphous silicon. The semiconductor material layer 140L can be deposited, for example, by chemical vapor deposition (CVD). The thickness of the semiconductor material layer 140L, as measured at a horizontal portion above the planarization dielectric layer 60, can be from 2 nm to 40 nm, although lesser and greater thicknesses can also be employed. The first and second gate cavities (25A, 25B) are not completely filled so that the inner surfaces of the semiconductor material layer 140 are physically exposed within the first and second gate cavities (25A, 25B).

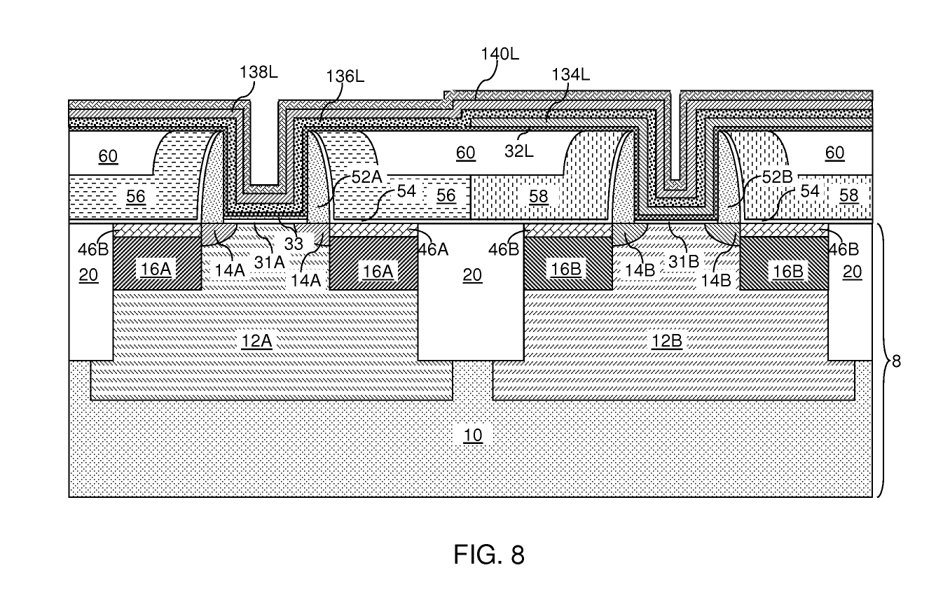

Referring to FIG. 8, a drive-in anneal is performed at an elevated temperature to induce diffusion of the metallic element(s) within the metal-containing layer 136L toward the gate dielectric layer 32L. The elevated temperature can be, for example, in a range from 400 degrees Celsius to 1,000 degrees Celsius, although lesser and greater temperatures can also be employed for the anneal. The anneal can be performed in a furnace or in a single wafer processing tool such as a rapid thermal anneal (RTA) chamber.

In the first device region, the metal-containing layer 136L is in contact with the gate dielectric layer 32L. Thus, the metallic element(s) within the metal-containing layer 136L diffuse(s) into the portion of the gate dielectric layer 32L that contacts the metal-containing layer 136L.

In one embodiment, the at least one metallic element within the metal-containing layer 136L diffuses through the gate dielectric layer 32L and at least to the interface between the first interfacial dielectric layer 31A and the gate dielectric layer 32L in the first device region. In one embodiment, the at least one metallic element from the metal-containing layer 136L can have a peak concentration at the interface between the first interfacial dielectric layer 31A and the gate dielectric layer 32L in the first device region.

In one embodiment, the at least one metallic element from the metal-containing layer 136L diffuses to the interface between the first interfacial dielectric layer 31A and the gate dielectric layer 32L in the first device region, and forms a dielectric compound by combining with the oxygen and/or the nitrogen that is/are present within the first interfacial dielectric layer 31A and/or the gate dielectric layer 32L. In this case, a planar metal-doped gate dielectric layer 33 is formed between the top surface of the first interfacial dielectric layer 31A and the portion of the gate dielectric layer 32L in the first device region. The planar metal-doped gate dielectric layer 33 includes a dielectric compound of the at least one metallic element from the metal-containing layer 136L, i.e., a dielectric compound of at least one element selected from Group IIA elements, Group IIIB elements, and Al, Ge, and Ti.

In one embodiment, the planar metal-doped gate dielectric layer 33 can be formed as a contiguous layer with the thickness of one or more monolayers of the dielectric compound of the at least one metallic element from the metal-containing layer 136L. In another embodiment, the planar metal-doped gate dielectric layer 33 can be formed as a layer including holes therein or as a discontinuous layer with the thickness of less than one monolayer of the dielectric compound of the at least one metallic element from the metal-containing layer 136L. In yet another embodiment, the planar metal-doped gate dielectric layer 33 can be formed as discrete islands embedded in the first interfacial dielectric layer 31A and/or the portion of the gate dielectric layer 32L in the first device region.

In one embodiment, the planar metal-doped gate dielectric layer 33 can be formed integrally with the first interfacial dielectric layer 31A as a top portion of the first interfacial dielectric layer 31A. In one embodiment, the planar metal-doped gate dielectric layer 33 can be formed integrally with the portion of the gate dielectric layer 32L in contact with the first interfacial layer 31A as a bottom portion of that portion of the gate dielectric layer 32L.

In one embodiment, the at least one metallic element from the metal-containing layer 136L can combine with oxygen atoms within the gate dielectric layer 32L to form a dielectric metal oxide that is different from the dielectric metal oxide of the gate dielectric layer 32L as deposited. In this case, the portion of the gate dielectric layer 32L in the first device region can be doped with the at least one metallic element from the metal-containing layer 136L.

In one embodiment, the at least one metallic element from the metal-containing layer 136L can combine with oxygen atoms within the first interfacial dielectric layer 31A to form a dielectric metal oxide that is different from the dielectric semiconductor oxide of the first interfacial dielectric layer 31A as deposited. In this case, the first interfacial dielectric layer 31A in the first device region can be doped with the at least one metallic element from the metal-containing layer 136L.

In the second device region, the diffusion barrier layer 134L blocks the diffusion of the at least one metallic element from the metal-containing layer 136L toward the gate dielectric layer 32L or the second interfacial dielectric layer 31B. Thus, the composition of the portion of the gate dielectric layer 32L in the second device region and the composition of the second interfacial dielectric layer 31B do not change during the anneal.

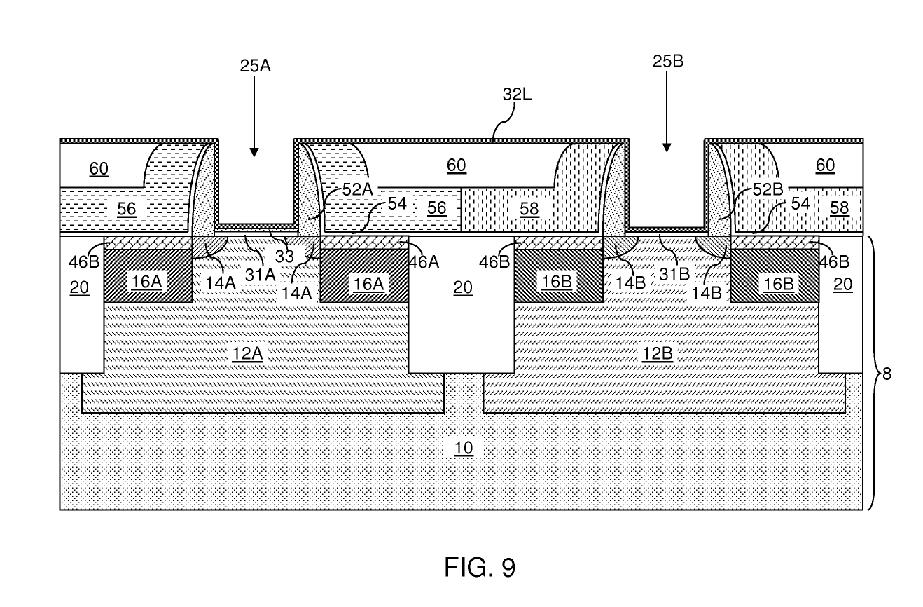

Referring to FIG. 9, the semiconductor material layer 140L, the sacrificial metal-containing cap layer 138L, the remaining metal-containing layer 136L if any, and the diffusion barrier layer 134L are sequentially removed. The removal of the various materials of the semiconductor material layer 140L, the sacrificial metal-containing cap layer 138L, the metal-containing layer 136L, and the diffusion barrier layer 134L can be effected by at least one wet etch and/or at least one dry etch. The removal of the metal-containing layer 136L and the diffusion barrier layer 134L is performed selective to the dielectric material of the gate dielectric layer 32L so that the gate dielectric layer 32L is not removed. An example of an etch chemistry that can be employed for such selective removal is a mixture of HCl and H₂O₂.

In one embodiment, a first stack of the first interfacial dielectric layer 31A and a first portion of the gate dielectric layer 32L in direct contact within the first interfacial dielectric layer 31A can have the same areal density of various elements within a second stack of the second interfacial dielectric layer 31B and a second portion of the gate dielectric layer 32L in direct contact within the second interfacial dielectric layer 31B, and additionally include the at least one metallic element that diffuse into the first stack during the drive-in anneal. In one embodiment, the at least one element that diffuse into the first stack during the drive-in anneal can be different from any element in the first stack or the second stack prior to the anneal. In this case, the first stack has a finite areal density of the at least one metallic element from the metal-containing layer 136L, while the second stack does not include any of the at least one metallic element that is present in the metal-containing layer 136L.

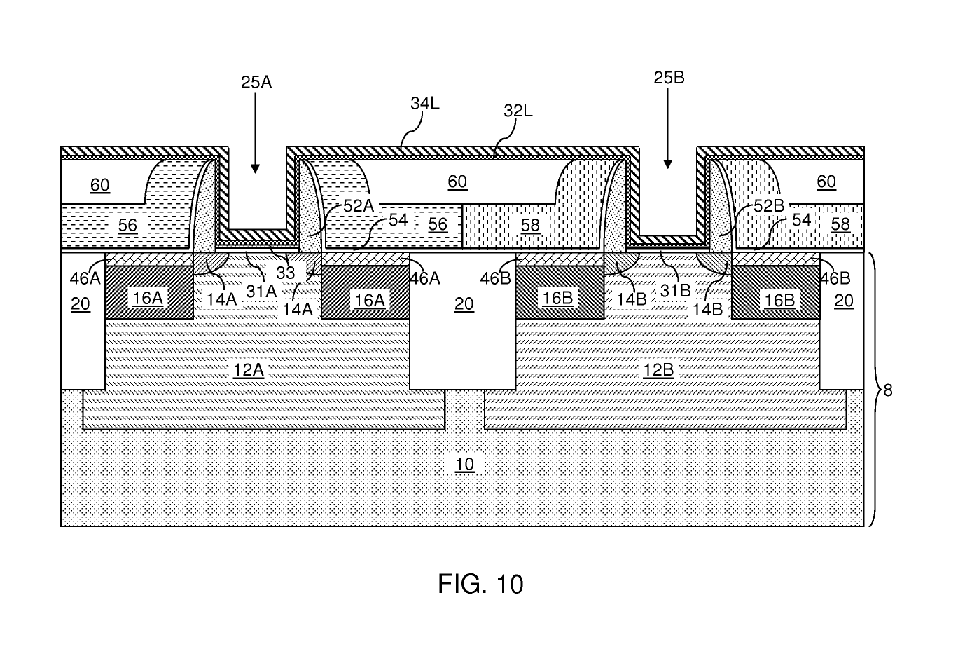

At least one workfunction material layer is subsequently formed within the first and second gate cavities (25A, 25B). Referring to FIG. 10, a first work function material layer 34L is deposited on the gate dielectric layer 32L. The material of the first work function material layer 34L has a first work function, and can be selected from any work function material known in the art. The first work function material layer 34L can include an elemental only, or can include a metallic compound, which includes a metal and a non-metal element. The metallic compound is selected to optimize the performance of the second field effect transistor to be subsequently formed in the second device region employing the second source and drain extension regions 14B, the second source and drain regions 16B, and the second doped well 12B. The metallic compound can be selected from tantalum carbide, metallic nitrides, and a hafnium-silicon alloy. Exemplary metallic nitrides include titanium nitride, tantalum nitride, tungsten nitride, and combinations and alloys thereof.

The first work function material layer 34L can be formed, for example, by physical vapor deposition, chemical vapor deposition, or atomic layer deposition (ALD). The thickness of the first work function material layer 34L is typically set at a value from 1 nm to 30 nm, and more typically, from 2 nm to 10 nm, although lesser and greater thicknesses can also be employed.

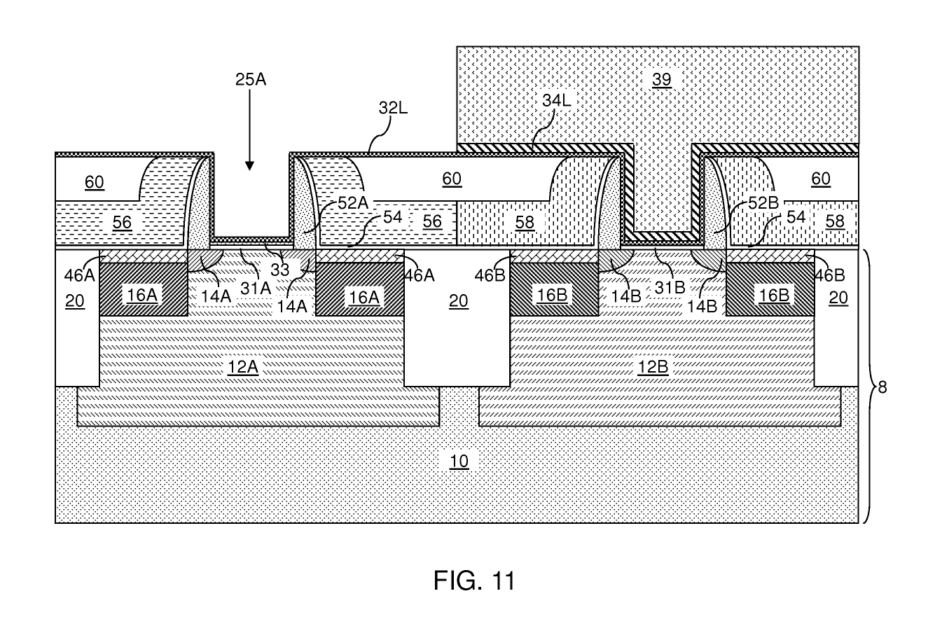

Referring to FIG. 11, a photoresist layer 39 is applied and lithographic patterned so that the photoresist layer 39 covers the area over the first doped well 12A, while the top surface of the first work function material layer 34L is exposed over the second doped well 12B. The pattern in the photoresist layer 39 is transferred into the first work function material layer 34L by an etch. The portion of the first work function material layer 34L within the first gate cavity 25A is removed employing the first photoresist 39 as an etch mask. The photoresist layer 39 is removed, for example, by ashing or wet etching. After the patterning of the first work function material layer 34L, a remaining portion of the first work function material layer 34L is present in the second device region and not present in the first device region. Correspondingly, the first work function material layer 34L is present in the second gate cavity 25B (See FIG. 10), but is not present in the first gate cavity 25A. The photoresist layer 39 is subsequently removed, for example, by ashing.

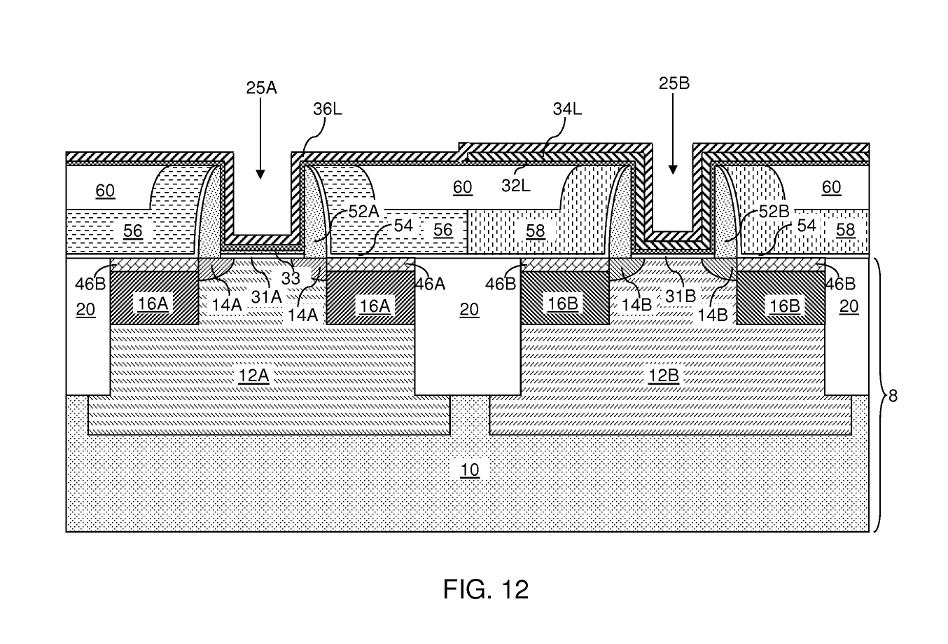

Referring to FIG. 12, a second work function material layer 36L is deposited. The second work function material layer 36L includes a second metal having a second work function, which can be different from the first work function. The material of the second work function material layer 36L h can be selected from any work function material known in the art. The material of the second work function material layer 36L is selected to optimize the performance of the first field effect transistor to be subsequently formed in the first device region employing the first source and drain extension regions 14A, the first source and drain regions 16A, and the first doped well 12B.

The second work function material layer 36L can be formed, for example, by physical vapor deposition, chemical vapor deposition, or atomic layer deposition (ALD). The thickness of the second work function material layer 36L is typically set at a value from 2 nm to 100 nm, and more typically, from 3 nm to 10 nm, although lesser and greater thicknesses can also be employed.

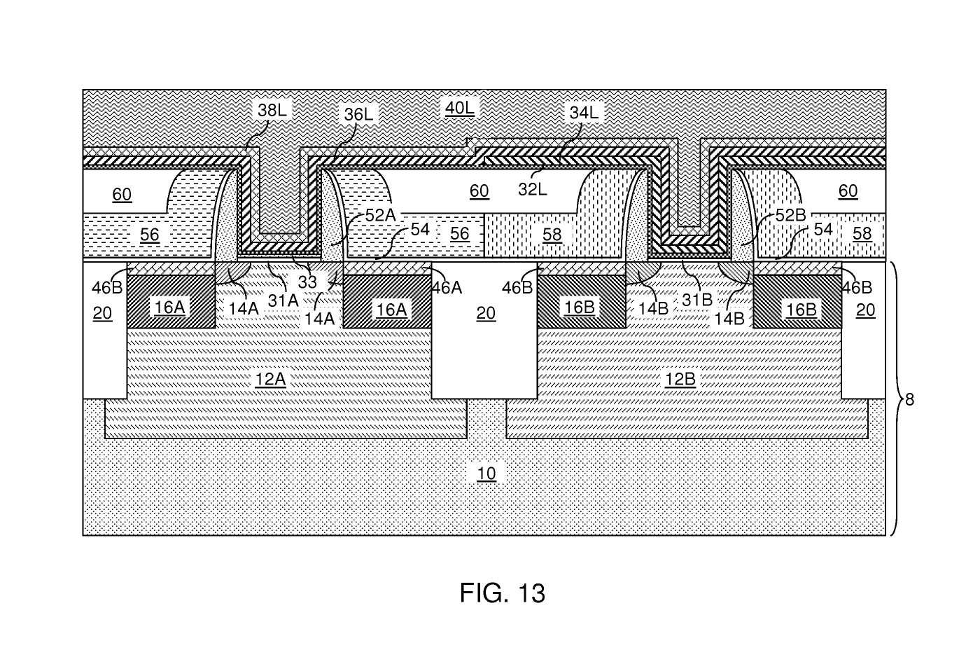

Referring to FIG. 13, an optional barrier metal layer 38L can deposited on the second work function material layer 36L. In a non-limiting illustrative example, the optional barrier metal layer 38L can include a tantalum nitride layer, a titanium nitride layer, a titanium-aluminum alloy, a titanium carbide layer, a tantalum carbide layer, or a combination thereof. The thickness of the optional barrier metal layer 38L can be from 0.5 nm to 20 nm, although lesser and greater thicknesses can also be employed. The optional barrier metal layer 38L may be omitted in some embodiments. In one embodiment, the optional barrier metal layer 38L includes a metallic nitride. For example, the optional barrier metal layer 38L can include titanium nitride.

A conductive material layer 40L can be deposited on the optional barrier metal layer 38L or on the second work function material layer 36L. The conductive material layer 40L can include a conductive material deposited by physical vapor deposition or chemical vapor deposition. For example, the conductive material layer 40L can be an aluminum layer, a tungsten layer, an aluminum alloy layer, or a tungsten alloy layer, and can be deposited by physical vapor deposition. The thickness of the conductive material layer 40L, as measured in a planar region of the conductive material layer 40L above the top surface of the planarization dielectric layer 60, can be from 100 nm to 500 nm, although lesser and greater thicknesses can also be employed. In one embodiment, the conductive material layer 40 consists essentially of a single elemental metal such as Al, or W. For example, the conductive material layer can consist essentially of aluminum.

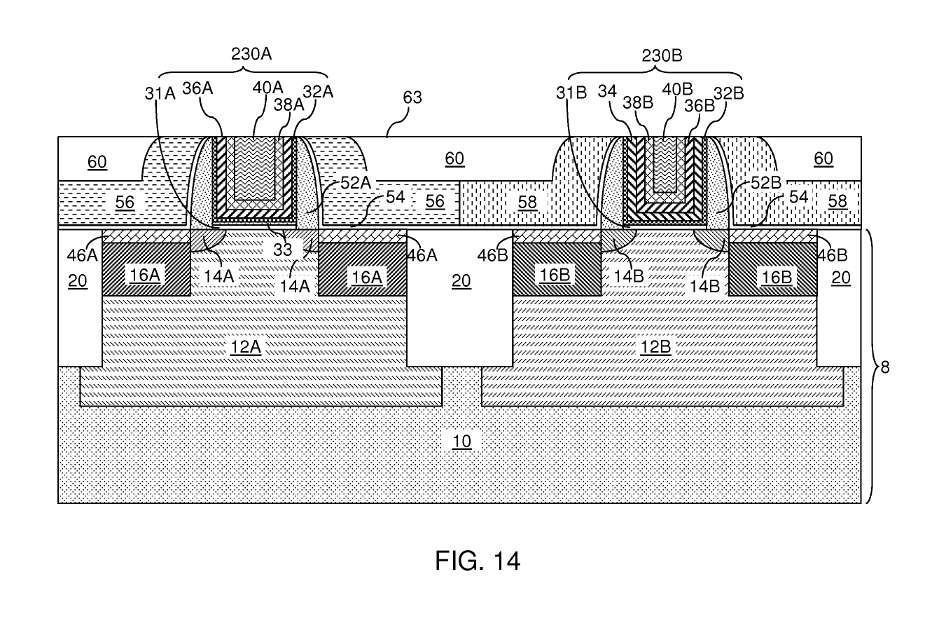

Referring to FIG. 14, portions of the gate conductor layer 40L, the optional barrier metal layer 38L, the second work function material layer 36L, the first work function material layer 34L, and the gate dielectric layer 32L are removed from above the planar dielectric surface 63 of the planarization dielectric layer 60 by employing a planarization process. Replacement gate stacks are formed by removing portions of the material layer stack from above a source region and a drain region of each field effect transistor. The replacement gate stacks include a first replacement gate stack 230A located in the first device region and a second replacement gate stack 230B located in the second device region. Each replacement gate stack (230A, 230B) overlies a channel region of a field effect transistor. The first replacement gate stack 230A and the second replacement gate stack 230B are formed concurrently.

The first field effect transistor is formed in the first device region. The first field effect transistor includes the first doped well 12A, the first source and drain extension regions 14A, the first source and drain regions 16A, first metal semiconductor alloy portions 46A, and a first replacement gate stack 230A. The first replacement gate stack 230A includes the first interfacial dielectric layer 31A, a planar metal-doped gate dielectric layer 33, a first high-k gate dielectric 32A which is a remaining portion of the gate dielectric layer 32L in the first device region, a second work function material portion 36A which is a remaining portion of the second work function material layer 36L in the first device region, a first optional barrier metal portion 38A which is a remaining portion of the optional barrier metal layer 38L, and a first gate conductor portion 40A which is a remaining portion of the gate conductor layer 40L.

The second field effect transistor is formed in the second device region. The second field effect transistor includes the second doped well 12B, the second source and drain extension regions 14B, the second source and drain regions 16B, a second metal semiconductor alloy portions 46B, and a second replacement gate stack 230B. The second replacement gate stack 230B includes the second interfacial dielectric layer 31B, a second high-k gate dielectric 32B which is a remaining portion of the gate dielectric layer 32L in the second device region, a first work function material portion 34 which is a remaining portion of the first work function material layer 34L, a metallic material portion 36B which is a remaining portion of the second work function material layer 36L in the second device region, a second optional barrier metal portion 38B which is a remaining portion of the optional barrier metal layer 38L, and a second gate conductor portion 40B which is a remaining portion of the gate conductor layer 40L. The second work function material portion 36A in the first replacement gate stack 230A and the metallic material portion 36B in the second replacement gate stack 230B have the same material composition and the same thickness.

The stack of the first interfacial dielectric layer 31A, the planar metal-doped gate dielectric layer 33, and the first high-k gate dielectric 32A is herein referred to as a first gate dielectric (31A, 33, 32A). The stack of the second interfacial dielectric layer 31B and the second high-k gate dielectric 32B is herein referred to as a second gate dielectric (31B, 32B). Each of the first and second high-k gate dielectrics (32A, 32B) is a U-shaped gate dielectric, which includes a horizontal gate dielectric portion and a vertical gate dielectric portion extending upward from peripheral regions of the horizontal gate dielectric portion. In the first field effect transistor, the second work function material portion 36A contacts inner sidewalls of the vertical gate dielectric portion of the first high-k gate dielectric 32A. In the second field effect transistor, the first work function material portion 34 contacts inner sidewalls of the vertical gate dielectric portion of the second high-k gate dielectric 32B.

In one embodiment, the first gate dielectric (31A, 33, 32A) can include the first interfacial dielectric layer 31A contacting a channel of the first field effect transistor, the planar metal-doped gate dielectric layer 33 contacting a top surface of the first interfacial dielectric layer 31A, and a first U-shaped gate dielectric layer, i.e., the first high-k gate dielectric 32A, having a horizontal portion in contact with the planar metal-doped gate dielectric layer 33 and a vertical portion that extends to a topmost portion of the first dielectric gate spacer 52A laterally surrounding the first U-shaped gate dielectric layer. The second gate dielectric (31B, 32B) can include the second interfacial dielectric layer 31B contacting a channel of the second field effect transistor, and a second U-shaped gate dielectric layer, i.e., the second high-k gate dielectric 32B, having a horizontal portion in contact with the second interfacial dielectric layer 31B and a vertical portion that extends to a topmost portion of a second dielectric gate spacer 52B laterally surrounding the second U-shaped gate dielectric layer. The planar metal-doped gate dielectric layer 33 includes an element selected from Group IIA elements, Group IIIB elements, Al, Ge, and Ti.

In one embodiment, the horizontal portion of the first U-shaped gate dielectric layer, i.e., the first high-k gate dielectric 32A, and the horizontal portion of the second U-shaped gate dielectric layer, i.e., the second high-k gate dielectric 32B, can have a same first composition and a same first thickness. The first interfacial dielectric layer 31A and the second interfacial dielectric layer 31B can have a same second composition and a same second thickness.

In one embodiment, the first U-shaped gate dielectric layer and the second U-shaped gate dielectric layer can include a dielectric metal oxide having a dielectric constant greater than 3.9. In one embodiment, the first interfacial dielectric layer 31A and the second interfacial dielectric layer 31B can include silicon oxide.

In one embodiment, the first field effect transistor includes a first gate electrode (36A, 38A, 40A) contacting inner sidewalls of the vertical portion of the first U-shaped gate dielectric layer, and the second field effect transistor includes a second gate electrode (24, 26B, 38B, 40B) contacting inner sidewalls of the vertical portion of the second U-shaped gate dielectric layer. The first and second gate electrodes can have different stacks of conductive materials, for example, due to the presence of the material of the first work function material portion 34 in the second gate electrode and the absence of the material of the first work function material portion 34 in the first gate electrode.

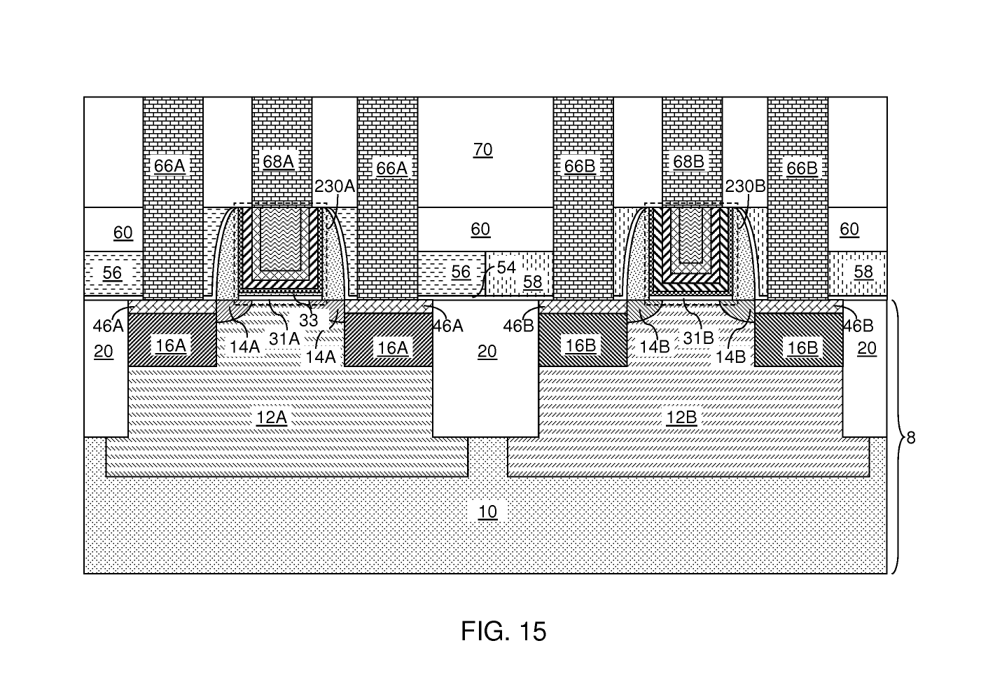

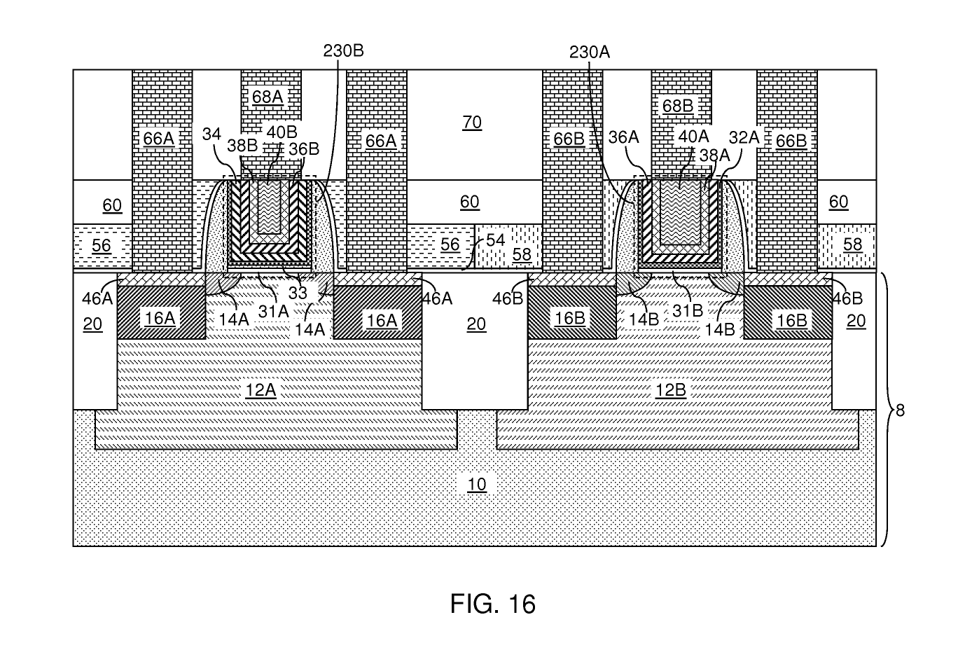

Referring to FIG. 15, a contact-level dielectric layer 70 is deposited over the planarization dielectric layer 60. Various contact via structures can be formed, for example, by formation of contact via cavities by a combination of lithographic patterning and an anisotropic etch followed by deposition of a conductive material and planarization that removes an excess portion of the conductive material from above the contact-level dielectric layer 70. The various contact via structures can include, for example, first source/drain contact via structures 66A, second source/drain contact via structures 66B, a first gate contact via structure 68A, and a second gate contact via structure 68B.

Referring to FIG. 16, a first variation of the first exemplary semiconductor structure according to the first embodiment of the present disclosure can be derived from the first exemplary semiconductor structure of FIG. 10 by removing the portion of the first work function material layer 34L from the second device region and preserving the portion of the first work function material layer 34L in the first device region instead of removing the portion of the first work function material layer 34L from the first device region and preserving the portion of the first work function material layer 34L. The processing steps of FIGS. 12-15 are sequentially performed subsequently. In this variation, the first replacement gate stack 230A is formed in the second device region, and the second replacement gate stack 230B is formed in the first device region.

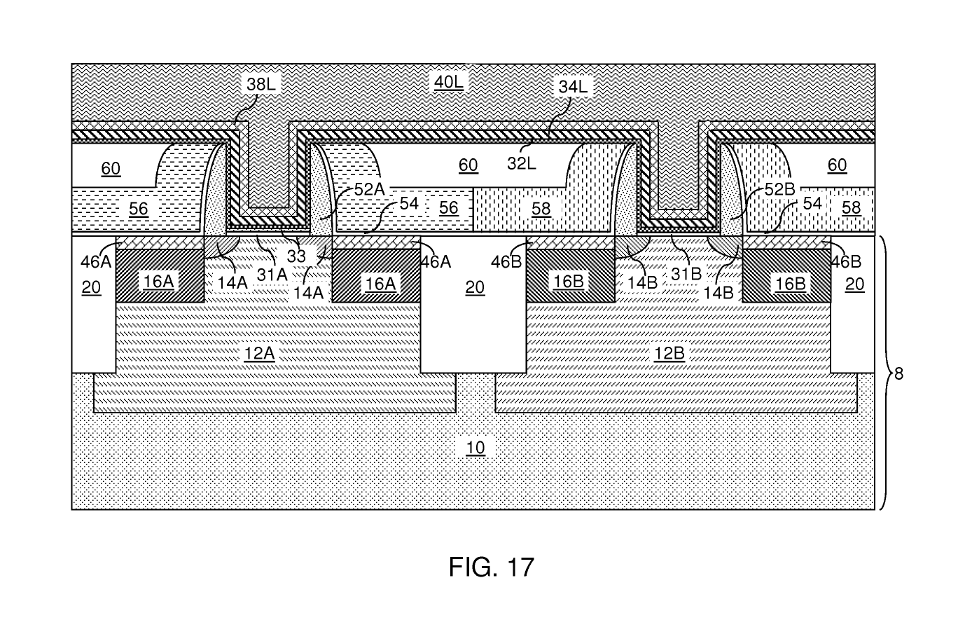

Referring to FIG. 17, a second variation of the first exemplary semiconductor structure according to the first embodiment of the present disclosure is derived from the first exemplary semiconductor structure of FIG. 10 by depositing the optional barrier metal layer 38L or the conductive material layer 40L shown in FIG. 13. Thus, the processing steps of FIGS. 11 and 12 are omitted in the second variation of the first exemplary semiconductor structure.

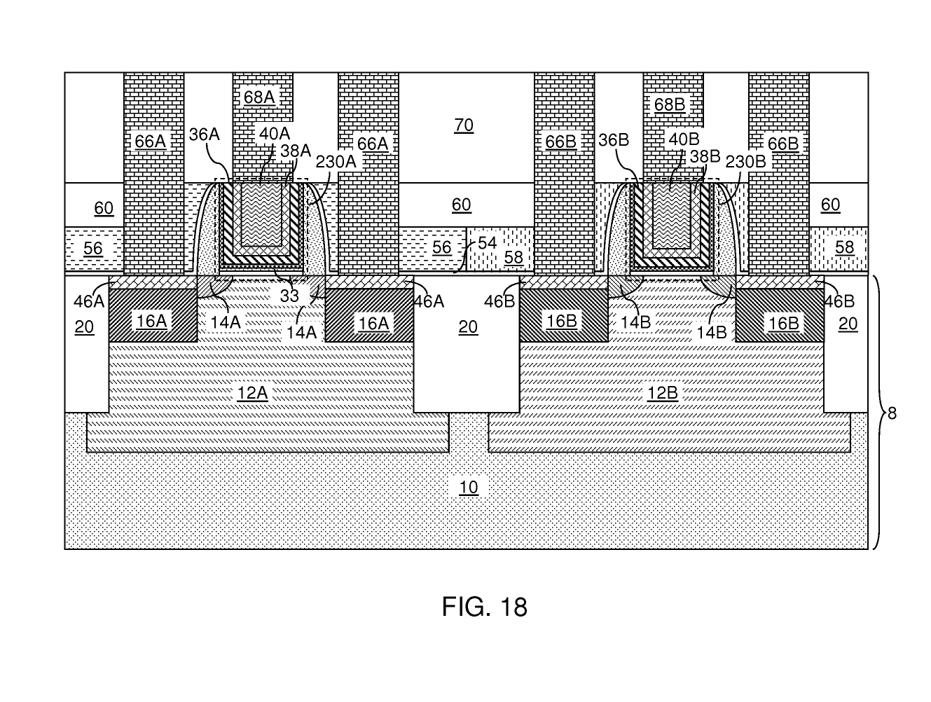

Referring to FIG. 18, a contact-level dielectric layer 70 and various contact via structures (66A, 66B, 68A, 68B) are formed employing the processing steps of FIGS. 14 and 15. In the second variation of the first exemplary semiconductor structure, a first gate electrode (36A, 38A, 40A) contacts inner sidewalls of the vertical portion of a first U-shaped gate dielectric layer, which is the first high-k gate dielectric 32A. The second field effect transistor includes a second gate electrode (36B, 38B, 40B) contacting inner sidewalls of the vertical portion of a second U-shaped gate dielectric layer, which is the second high-k gate dielectric layer 32B. The first gate electrode (36A, 38A, 40A) and second gate electrodes (36B, 38B, 40B) have a same stack of conductive materials.

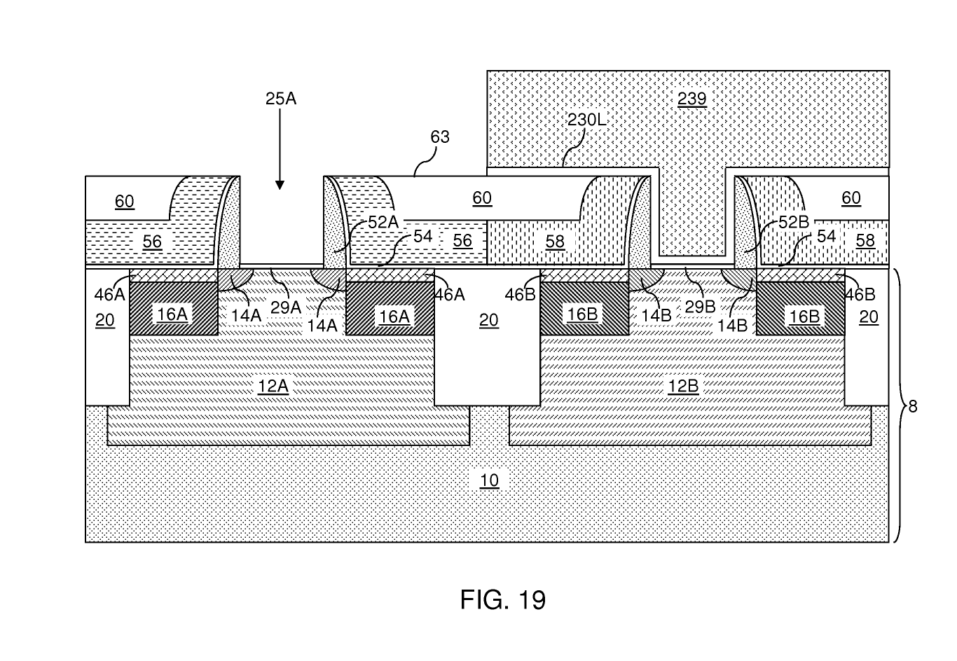

Referring to FIG. 19, a second exemplary semiconductor structure according to a second embodiment of the present disclosure is derived from the first exemplary semiconductor structure of FIG. 1A by removing the first and second disposable gate material portions (27A, 27B) selective to the dielectric materials of the planarization dielectric layer 60, the first stress-generating liner 58 and/or the second stress-generating liner 56 (if present), and the first and second dielectric gate spacers (52A, 52B). The disposable dielectric portions (29A, 29B) may, or may not, be removed at this step.

An optional dielectric liner 230L may be applied over the planarization dielectric layer 60 and within the first and second gate cavities (25A, 25B; See FIG. 2). A photoresist layer 239 is applied over the optional dielectric liner 230L or over the planarization dielectric layer 60 and within the first and second gate cavities (25A, 25B). The photoresist layer 239 is lithographically patterned by lithographic exposure and development such that a remaining portion of the photoresist layer 239 covers the second device region, and does not cover the first device region. The optional dielectric liner 230L may be patterned employing the patterned photoresist layer 239 as an etch mask so that the optional dielectric liner 230L is removed form the first device region.

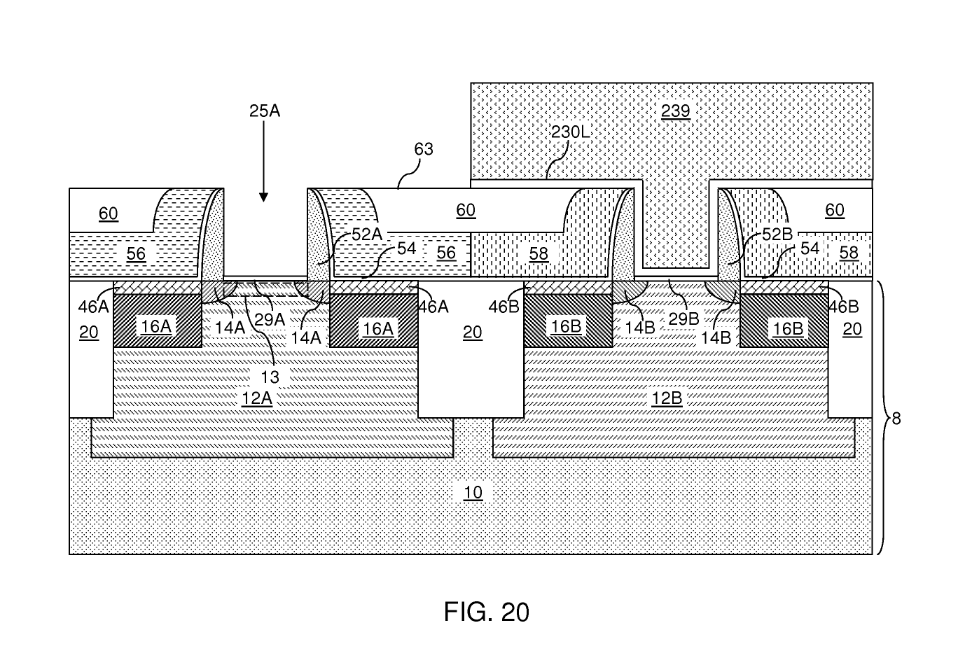

Referring to FIG. 20, carbon is implanted through the first gate cavity 25A and the first disposable dielectric portion 29A and into an upper portion of the first doped well 12A to form a carbon doped region 13. The carbon doped region 13 can be formed directly underneath the interface between the first doped well 12A and the first disposable dielectric portion 29A, which is the channel region of a first field effect transistor to be subsequently formed within the first device region. The carbon implantation is performed through only the first disposable dielectric portion 29A, and not through the second disposable dielectric portion 29B, to form the carbon doped region 13 within the semiconductor substrate 8.

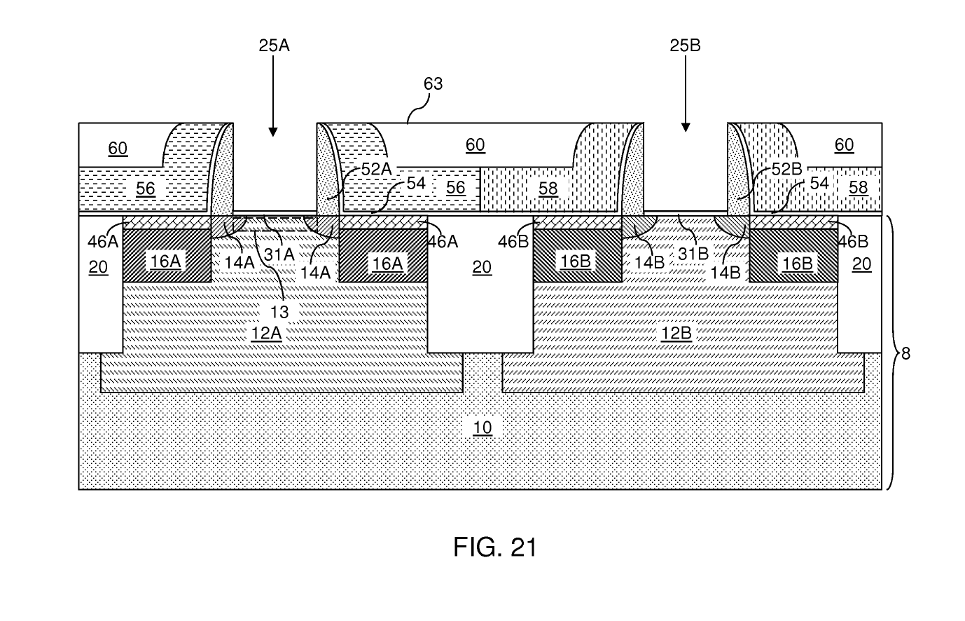

Referring to FIG. 21, the photoresist layer 239 is removed, for example, by ashing. The optional dielectric liner 230L can be removed, for example, by a wet etch. A first interfacial dielectric layer 31A is formed on the semiconductor surface at the bottom of the first gate cavity 25A, and a second dielectric layer 31B is formed on the semiconductor surface at the bottom of the second gate cavity 25B employing the same methods as in FIG. 2 of the first embodiment. Only one of the first interfacial dielectric layer 31A and the second interfacial dielectric layer 31B, and specifically only the first interfacial dielectric layer 31A, is formed over the carbon doped region 13.

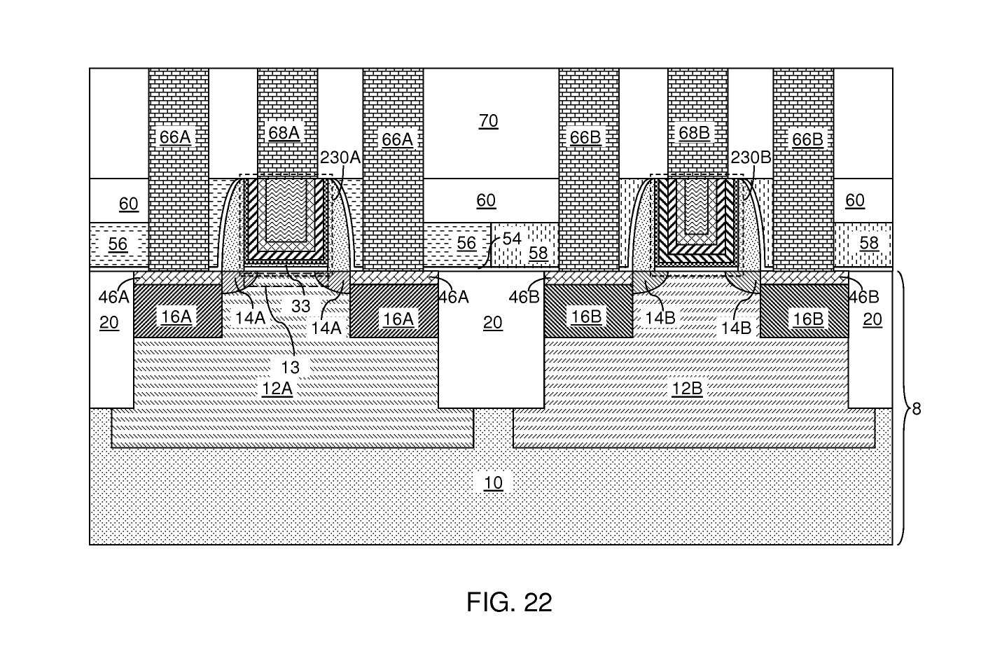

Referring to FIG. 22, the processing steps of FIGS. 3-15 of the first embodiment can be performed to form the second exemplary semiconductor structure of FIG. 22. Alternately, the processing steps employed to form the first or second variation of the first exemplary semiconductor structure can be employed to form variations of the second exemplary semiconductor structure. The first field effect transistor includes the carbon doped region 13 within the channel of the first field effect transistor. The second field effect transistor does not include any carbon doped region. Formation of the carbon doped region 13 can be particularly beneficial if the first field effect transistor is an n-type field effect transistor. In this case, the leakage current and sub-threshold voltage slope can be improved by the presence of the carbon doped region 13 due to the presence of the carbon doped region 13 within the channel of the first field effect transistor.

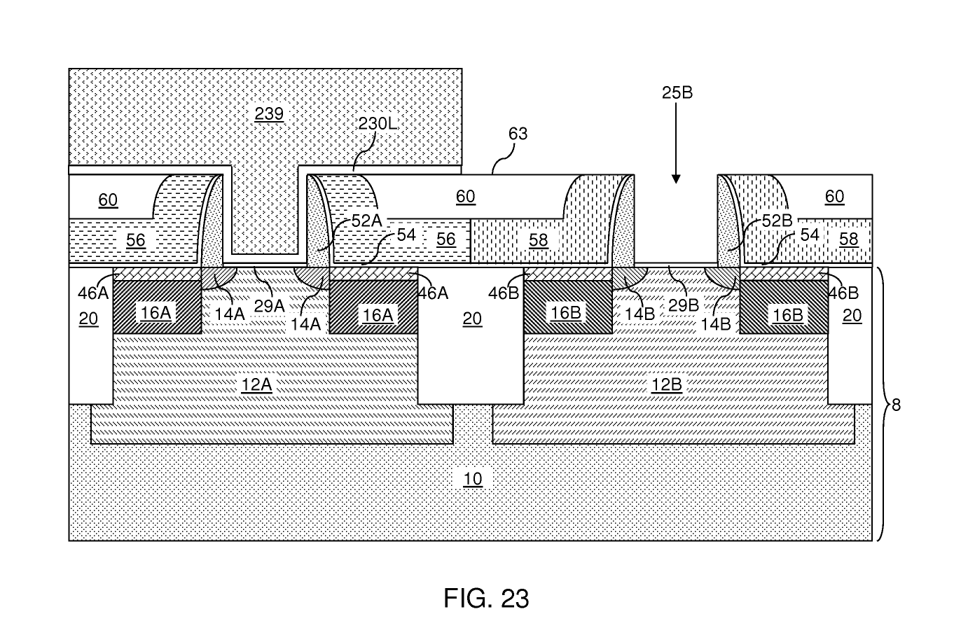

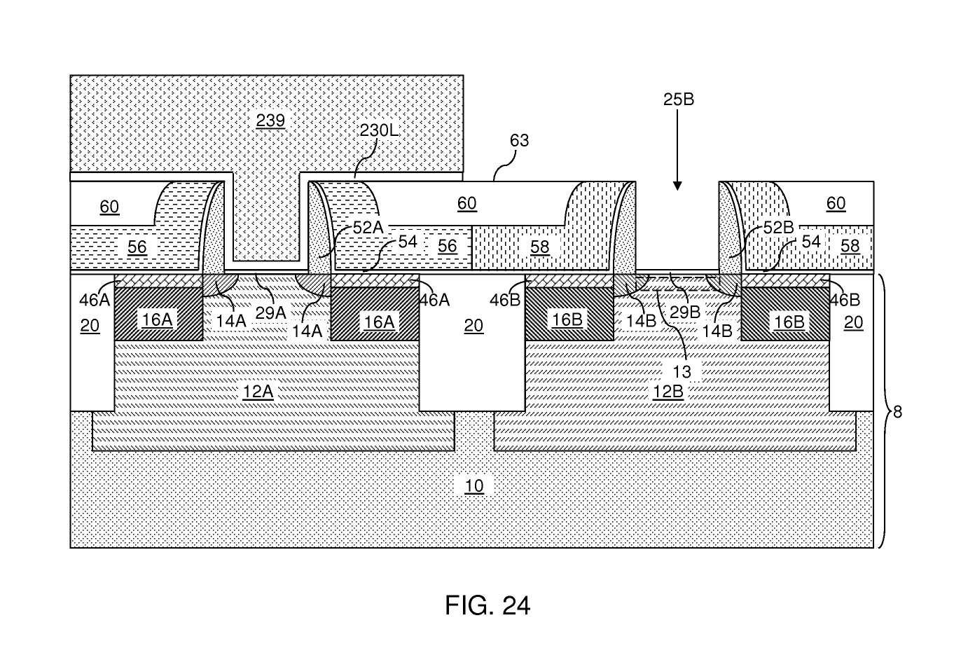

Referring to FIG. 23, a third exemplary semiconductor structure according to a third embodiment of the present disclosure is derived from the first exemplary semiconductor structure of FIG. 1A by removing the first and second disposable gate material portions (27A, 27B) selective to the dielectric materials of the planarization dielectric layer 60, the first stress-generating liner 58 and/or the second stress-generating liner 56 (if present), and the first and second dielectric gate spacers (52A, 52B). The disposable dielectric portions (29A, 29B) may, or may not, be removed at this step.

An optional dielectric liner 230L may be applied over the planarization dielectric layer 60 and within the first and second gate cavities (25A, 25B; See FIG. 2). A photoresist layer 239 is applied over the optional dielectric liner 230L or over the planarization dielectric layer 60 and within the first and second gate cavities (25A, 25B). The photoresist layer 239 is lithographically patterned by lithographic exposure and development such that a remaining portion of the photoresist layer 239 covers the first device region, and does not cover the second device region. The optional dielectric liner 230L may be patterned employing the patterned photoresist layer 239 as an etch mask so that the optional dielectric liner 230L is removed form the second device region.

Referring to FIG. 24, carbon is implanted through the second gate cavity 25B and the second disposable dielectric portion 29B and into an upper portion of the second doped well 12B to form a carbon doped region 13. The carbon doped region 13 can be formed directly underneath the interface between the second doped well 12A and within the second disposable dielectric portion 29B, which is the channel region of a second field effect transistor to be subsequently formed within the second device region. The carbon implantation is performed through only the second disposable dielectric portion 29B, and not through the first disposable dielectric portion 29A, to form the carbon doped region 13 within the semiconductor substrate 8.

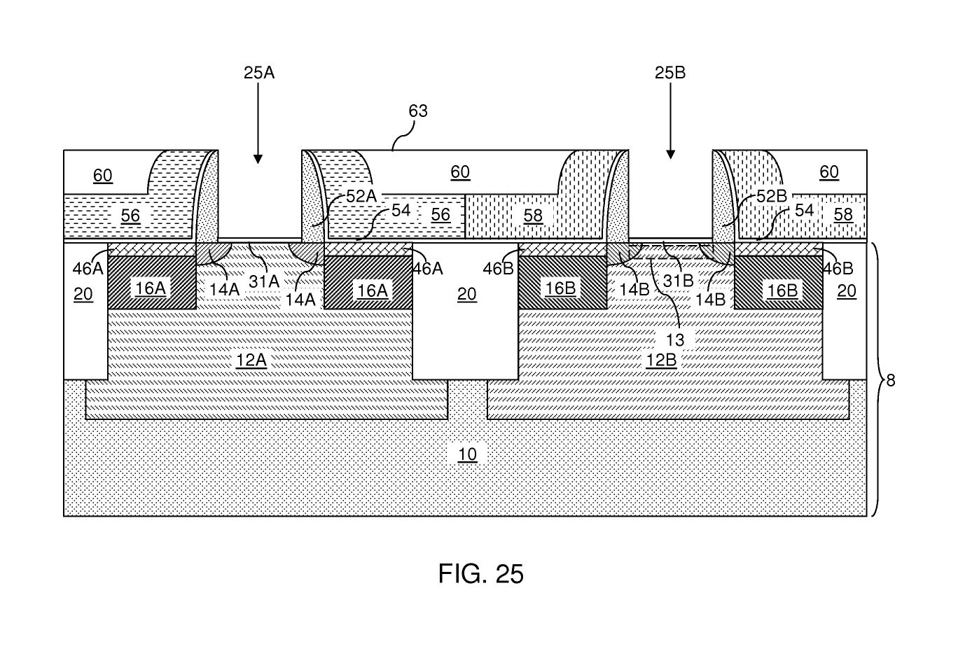

Referring to FIG. 25, the photoresist layer 239 is removed, for example, by ashing. The optional dielectric liner 230L can be removed, for example, by a wet etch. A first interfacial dielectric layer 31A is formed on the semiconductor surface at the bottom of the first gate cavity 25A, and a second dielectric layer 31B is formed on the semiconductor surface at the bottom of the second gate cavity 25B employing the same methods as in FIG. 2 of the first embodiment. Only one of the first interfacial dielectric layer 31A and the second interfacial dielectric layer 31B, and specifically only the second interfacial dielectric layer 31A, is formed over the carbon doped region 13.

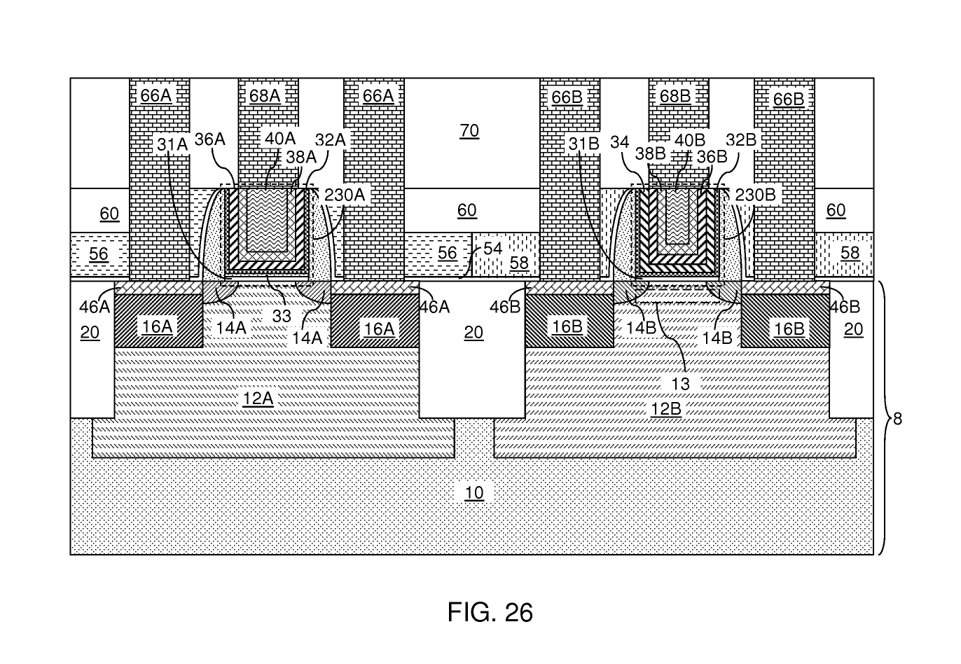

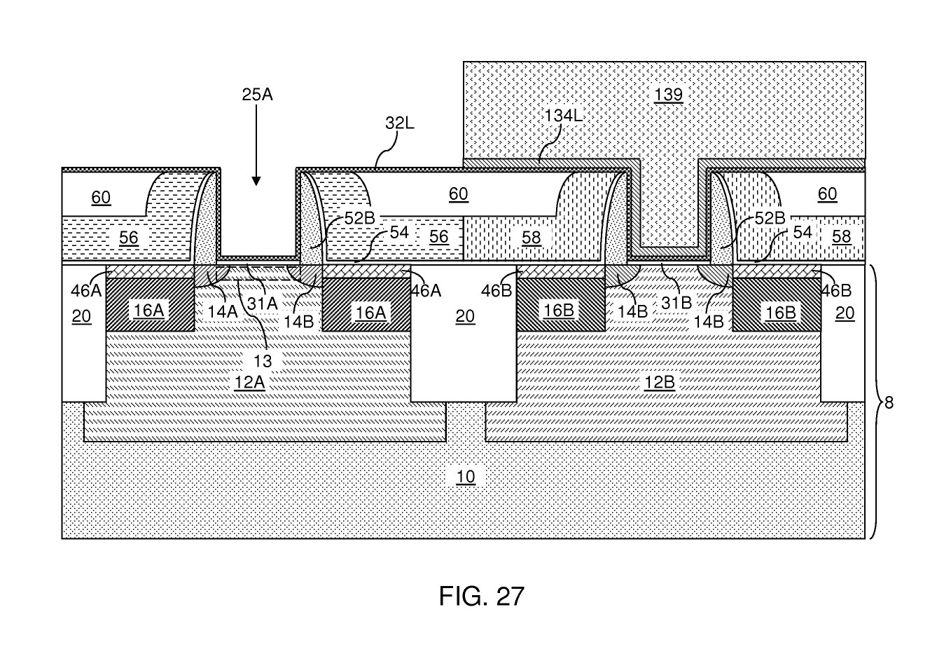

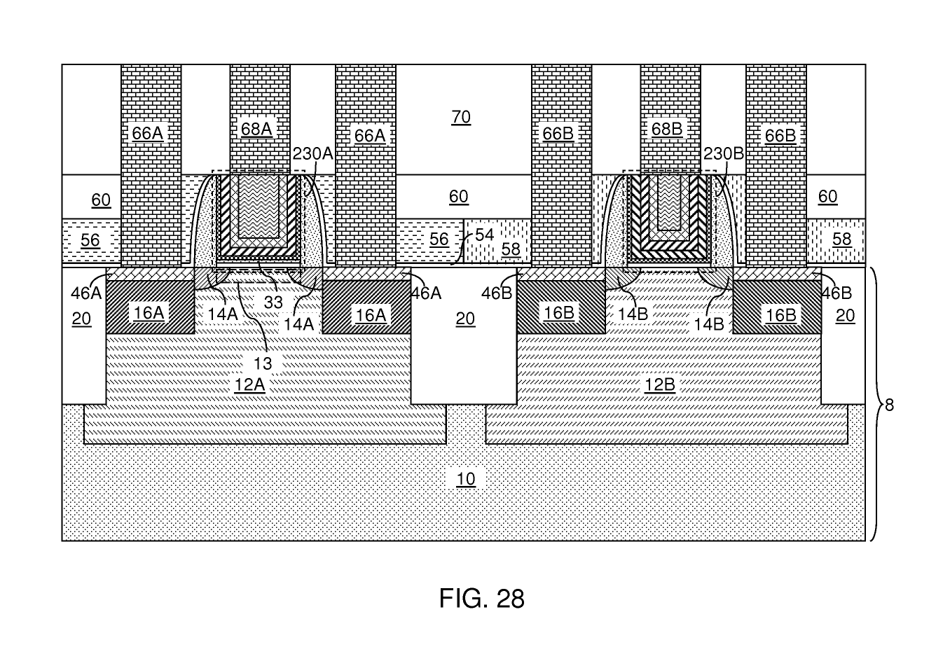

Referring to FIG. 26, the structure of FIG. 26. Alternately, the processing steps employed to form the first or second variation of the first exemplary semiconductor structure can be employed to form variations of the third exemplary semiconductor structure. The stack of the first interfacial dielectric layer 31A, the planar metal-doped gate dielectric layer 33, and the first high-k gate dielectric 32A is herein referred to as a first gate dielectric (31A, 33, 32A). The stack of the second interfacial dielectric layer 31B and the second high-k gate dielectric 32B is herein referred to as a second gate dielectric (31B, 32B). Each of the first and second high-k gate dielectrics (32A, 32B) is a U-shaped gate dielectric, which includes a horizontal gate dielectric portion and a vertical gate dielectric portion extending upward from peripheral regions of the horizontal gate dielectric portion. In the first field effect transistor, the second work function material portion 36A contacts inner sidewalls of the vertical gate dielectric portion of the first high-k gate dielectric 32A. In the second field effect transistor, the first work function material portion 34 contacts inner sidewalls of the vertical gate dielectric portion of the second high-k gate dielectric 32B.

The second field effect transistor includes the carbon doped region 13 within the channel of the first field effect transistor. The first field effect transistor does not include any carbon doped region. Formation of the carbon doped region 13 can be particularly processing steps of FIGS. 3-15 of the first embodiment can be performed to form the third exemplary semiconductor beneficial if the second field effect transistor is an n-type field effect transistor. In this case, the leakage current and sub-threshold voltage slope can be improved by the presence of the carbon doped region 13 due to the presence of the carbon doped region 13 within the channel of the second field effect transistor.

Referring to FIG. 27, a fourth exemplary semiconductor structure according a fourth embodiment of the present disclosure can be derived from the first exemplary semiconductor structure of FIG. 5 by implanting carbon atoms employing the photoresist layer 139 as an implantation mask. Thus, carbon is implanted through the first gate cavity 25A and the first interfacial dielectric layer 31A and into an upper portion of the first doped well 12A to form the carbon doped region 13. The carbon doped region 13 can be formed directly underneath the interface between the first doped well 12A and the first interfacial dielectric layer 31A, which is the channel region of a first field effect transistor to be subsequently formed within the first device region. The carbon implantation is performed through only the first interfacial dielectric layer 31A, and not through the second interfacial dielectric layer 31B, to form the carbon doped region 13 within the semiconductor substrate 8.

Referring to FIG. 28, the processing steps of FIGS. 6-15 of the first embodiment can be performed to form the fourth exemplary semiconductor structure of FIG. 28. Alternately, the processing steps employed to form the first or second variation of the first exemplary semiconductor structure can be employed to form variations of the fourth exemplary semiconductor structure. The first field effect transistor includes the carbon doped region 13 within the channel of the first field effect transistor. The second field effect transistor does not include any carbon doped region. Formation of the carbon doped region 13 can be particularly beneficial if the first field effect transistor is an n-type field effect transistor. In this case, the leakage current and sub-threshold voltage slope can be improved by the presence of the carbon doped region 13 due to the presence of the carbon doped region 13 within the channel of the first field effect transistor.

While the present disclosure has been described employing a planar MOSFET, the method and the structure of the present disclosure can be implemented on a planar JFET, a fin MOSFET, a fin JFET, and many other variations of field effect transistors known in the art. All such variations are contemplated herein.

While the disclosure has been described in terms of specific embodiments, it is evident in view of the foregoing description that numerous alternatives, modifications and variations will be apparent to those skilled in the art. Each of the various embodiments of the present disclosure can be implemented alone, or in combination with any other embodiments of the present disclosure unless expressly disclosed otherwise or otherwise impossible as would be known to one of ordinary skill in the art. Accordingly, the disclosure is intended to encompass all such alternatives, modifications and variations which fall within the scope and spirit of the disclosure and the following claims.

1. A semiconductor structure comprising:
a first field effect transistor having a first gate dielectric, said first gate dielectric comprising a first interfacial dielectric layer contacting a channel of said first field effect transistor, a planar metal-doped gate dielectric layer contacting a top surface of said first interfacial dielectric layer, and a first U-shaped gate dielectric layer having a horizontal portion in contact with said planar metal-doped gate dielectric layer and a vertical portion that extends to a topmost portion of a first dielectric gate spacer laterally surrounding said first U-shaped gate dielectric layer; and
a second field effect transistor having a second gate dielectric, said second gate dielectric comprising a second interfacial dielectric layer contacting a channel of said second field effect transistor, and a second U-shaped gate dielectric layer having a horizontal portion in contact with said second interfacial dielectric layer and a vertical portion that extends to a topmost portion of a second dielectric gate spacer laterally surrounding said second U-shaped gate dielectric layer.

2. The semiconductor structure of claim 1, wherein said horizontal portion of said first U-shaped gate dielectric layer and said horizontal portion of said second U-shaped gate dielectric layer have a same first composition and a same first thickness.

3. The semiconductor structure of claim 2, wherein said first interfacial dielectric layer and said second interfacial dielectric layer have a same second composition and a same second thickness.

4. The semiconductor structure of claim 2, wherein said first U-shaped gate dielectric layer and said second U-shaped gate dielectric layer comprise a dielectric metal oxide having a dielectric constant greater than 3.9.

5. The semiconductor structure of claim 4, wherein said first interfacial dielectric layer and said second interfacial dielectric layer comprise silicon oxide or silicon oxinitride.

6. The semiconductor structure of claim 2, wherein said planar metal-doped gate dielectric layer comprises an element selected from Group IIA elements, Group IIIB elements, Al, Ge, and Ti.

7. The semiconductor structure of claim 1, wherein said first field effect transistor further comprises a carbon doped region within said channel of said first field effect transistor.

8. The semiconductor structure of claim 1, wherein said second field effect transistor further comprises a carbon doped region within said channel of said second field effect transistor.

9. The semiconductor structure of claim 1, wherein said first field effect transistor comprises a first gate electrode contacting inner sidewalls of said vertical portion of said first U-shaped gate dielectric layer, and said second field effect transistor comprises a second gate electrode contacting inner sidewalls of said vertical portion of said second U-shaped gate dielectric layer, wherein said first and second gate electrodes have a same stack of conductive materials.

10. The semiconductor structure of claim 1, wherein said first field effect transistor comprises a first gate electrode contacting inner sidewalls of said vertical portion of said first U-shaped gate dielectric layer, and said second field effect transistor comprises a second gate electrode contacting inner sidewalls of said vertical portion of said second U-shaped gate dielectric layer, wherein said first and second gate electrodes have different stacks of conductive materials.

11-20. (canceled)

21. The semiconductor structure of claim 1, wherein said planar metal-doped gate dielectric layer comprises one of Be, Mg, Ca, Sr, Ba and Ra.

22. The semiconductor structure of claim 1, wherein said planar metal-doped gate dielectric layer comprises one of Sc, Y, a Lanthanide element and an Actinide element.

23. The semiconductor structure of claim 1, wherein said planar metal-doped gate dielectric layer is a contiguous layer with a thickness of one or more monolayers.

24. The semiconductor structure of claim 1, wherein said planar metal-doped gate dielectric layer is a discontinuous layer with a thickness of less than one monolayer.

25. The semiconductor structure of claim 1, wherein said planar metal-doped gate dielectric layer comprises discrete islands embedded in said first interfacial dielectric layer, said first gate dielectric, or a combination thereof.

26. The semiconductor structure of claim 1, wherein said planar metal-doped gate dielectric layer is located in a top portion of the first dielectric interfacial layer.

27. The semiconductor structure of claim 1, wherein said planar metal-doped gate dielectric layer is located in a bottom portion of said first gate dielectric which contacts said first dielectric interfacial layer.
